(19) United States
(12) Patent Application Publication
(10) Pub. No.: US 2026/0026066 A1
(43) Pub. Date: Jan. 22, 2026

(54) Sacrificial Dielectric Interposer with Bottom Source/Drain Insulation for Multigate Device

(71) Applicant: Taiwan Semiconductor Manufacturing Company, Ltd., Hsin-Chu (TW)

(72) Inventors: Szu-Chi YANG, Hsinchu City (TW); Wan-Ju TUNG, Taichung City (TW); Shi-Sheng HU, Tainan City (TW); Yi Wen XIAO, Hsinchu County (TW); Tsung-Hung LEE, Hsinchu City (TW); Chien-Tai CHAN, Hsinchu City (TW); Ming-Lung CHENG, Kaohsiung County (TW); Chih Chieh YEH, Taipei City (TW); Shih-Hao FU, Taoyuan County (TW); Li-Chi YU, Hsinchu County (TW); I-Hsieh WONG, Hsinchu (TW); Tzu-Hua CHIU, Hsinchu (TW); Chia-Pin LIN, Hsinchu County (TW)

(21) Appl. No.: 19/027,712

(22) Filed: Jan. 17, 2025

Related U.S. Application Data
(60) Provisional application No. 63/673,468, filed on Jul. 19, 2024.

(51) Int. Cl. H10D 64/01; H01L 21/28; H10D 30/01; H10D 62/00; H10D 84/83

(52) U.S. Cl. CPC H10D 64/017; H01L 21/28017; H10D 30/0191; H10D 62/021; H10D 84/832

(57) ABSTRACT

Methods of fabricating multigate transistors using dummy oxide interposers are disclosed herein. An exemplary method includes forming a multilayer stack that includes first semiconductor layers, sacrificial semiconductor layers, and a substrate extension. A source/drain recess is formed by removing the first semiconductor layers, sacrificial semiconductor layers, and a portion of the substrate extension in a source/drain region, and a source/drain structure is formed in the source/drain recess. The source/drain structure includes a second semiconductor layer and an insulator layer, and the insulator layer is disposed between the second semiconductor layer and the substrate extension. Before forming the source/drain structure, the sacrificial semiconductor layers are replaced with sacrificial dielectric layers. After forming the source/drain structure, the sacrificial dielectric layers are removed from a channel region to form a portion of a gate opening. A gate stack is formed in the portion of the gate opening.

This is a non-provisional application of and claims benefit of U.S. Provisional Patent Application Ser. No. 63/673,468, filed Jul. 19, 2024, the entire disclosure of which is incorporated herein by reference.

### BACKGROUND

Recently, multigate devices, which have gates that extend, partially or fully, around a channel to provide access to the channel on at least two sides, have been introduced to improve gate control. Exemplary multigate devices include fin-like field effect transistors (FinFETs) and gate-all around (GAA) transistors, such as nanowire transistors. Multigate devices enable aggressive scaling down of integrated circuit (IC) technologies, maintaining gate control, and mitigating short-channel effects (SCEs), while seamlessly integrating with existing IC manufacturing processes and/or techniques. As multigate devices continue to scale, advanced techniques are needed for optimizing multigate device reliability and/or performance.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method, in portion or entirety, for fabricating a multigate device (e.g., a p-type transistor), according to various aspects of the present disclosure.

FIG. 2 is a top view of a device, in portion or entirety, having bottom source/drain insulation that may be fabricated by a method that implements sacrificial dielectric interposers, such as by the method of FIG. 1, according to various aspects of the present disclosure.

FIGS. 3A-19A are diagrammatic cross-sectional views of the device, in portion or entirety, of FIG. 2 along line A-A at various stages of fabrication, such as those associated with the method of FIG. 1, according to various aspects of the present disclosure.

FIGS. 3B-19B are diagrammatic cross-sectional views of the device, in portion or entirety, of FIG. 2 along line B-B at various stages of fabrication, such as those associated with the method of FIG. 1, according to various aspects of the present disclosure.

FIG. 17C is a cross-sectional view of the device, in portion or entirety, of FIG. 2 along line C-C at the stage of fabrication of FIG. 17A and FIG. 17B, according to various aspects of the present disclosure.

FIGS. 20-22 are cross-sectional views of the device, in portion or entirety, of FIG. 2 along line A-A at various stages of fabrication, such as those associated with the method of FIG. 1, according to various aspects of the present disclosure.

FIG. 23 and FIG. 24 are cross-sectional views of the device, in portion or entirety, of FIG. 2 along line A-A at various stages of fabrication, such as those associated with the method of FIG. 1, according to various aspects of the present disclosure.

FIG. 25A and FIG. 25B are cross-sectional views of devices, in portion or entirety, that may be fabricated by a method that implements sacrificial dielectric interposers, such as by the method of FIG. 1, according to various aspects of the present disclosure.

FIG. 26A and FIG. 26B are plots illustrating performance differences between devices having source/drain structures configured with and without bottom source/drain insulation, according to various aspects of the present disclosure.

FIG. 27 is a cross-sectional view of a device, in portion or entirety, that may implement bottom source/drain insulation, according to various aspects of the present disclosure.

### DETAILED DESCRIPTION

The present disclosure relates generally to multigate devices, such as gate-all-around transistors, and methods of fabrication thereof for improving overall performance.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Furthermore, when a number or a range of numbers is described with “about,” “approximate,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−20% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +1-15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

Multigate devices include a gate structure that extends, partially or fully, around a channel region to provide access to a channel region on at least two sides. One such multigate device is the gate-all around (GAA) device, which includes channel layers (regions) that are vertically or horizontally stacked and suspended in a manner over a substrate that allows a gate stack to wrap around (or surround) and engage the channel layers. The channel layers extend between a source region and a drain region (e.g., epitaxial source/drains), and voltage can be applied to the gate stack, the source region, and/or the drain region to control a flow of current between the source region and the drain region. GAA devices can significantly increase contact area between the gate stack and the channel regions, which has been observed to decrease subthreshold swing (SS), decrease short channel effects (SCEs), increase drive current, and/or improve channel control compared to other multigate devices, such as FinFETs.

However, leakage current of GAA devices has arisen as a significant challenge as integrated circuit (IC) technology nodes scale (i.e., by increasing device density (i.e., the number of interconnected devices in a given chip area) and/or decreasing geometry size (e.g., dimensions and/or sizes of device features and/or spacings therebetween)). For example, a parasitic transistor may form between the gate stack, an elevated portion of the substrate (over which the channel layers and the gate stack are disposed), and the epitaxial source/drains, and current may undesirably flow/leak through the elevated portion of the substrate between the epitaxial source/drains. Since the gate stack may wrap the elevated portion of the substrate as opposed to surrounding it like the channel layers, the gate stack's control of the off-state leakage current in the elevated portion of the substrate may be limited to three sides (e.g., tri-gate control), which has proved insufficient as IC technology nodes scale and has been observed to induce and/or exacerbate drain-induced-barrier-lowering (DIBL) and degrade performance.

The present disclosure proposes inserting insulator materials (e.g., dielectric layers) and/or less conductive materials (e.g., bottom undoped epitaxial layers) between the epitaxial source/drains and the substrate to reduce leakage current through the underlying substrate and/or the elevated portion of the substrate (hereinafter referred to as a mesa). However, the present disclosure further recognizes that epitaxial source/drains formed on insulator materials (e.g., over non-crystalline surfaces), instead of semiconductor materials, may exhibit less strain/stress than epitaxial source/drains formed on semiconductor materials, such that incorporating insulator materials into source/drain structures may reduce parasitic capacitance and/or leakage current while also undesirably reducing desired source/drain strain/stress. In particular, p-type epitaxial source/drains (e.g., p-doped silicon germanium source/drains) formed over insulator layers may exhibit significant stress loss that degrades p-type transistor performance.

The present disclosure thus proposes reducing other undesired stresses that may be introduced into the epitaxial source/drains and/or the channels of a transistor during fabrication to compensate for the source/drain stress loss that may be caused by incorporating bottom source/drain isolation therein. For example, the present disclosure recognizes that sacrificial, dummy semiconductor layers (e.g., sacrificial silicon germanium (SiGe) layers, which may be referred to as sacrificial SiGe interposers) interleaved between semiconductor layers in a channel region (which become channel layers of a transistor) may induce undesired stress into channel layers, such as undesired tensile stress into channel layers of a p-type transistor. The present disclosure thus proposes replacing the sacrificial, dummy semiconductor layers with sacrificial, dummy dielectric layers, such as dummy oxide layers (which may be referred to as dummy oxide interposers), to eliminate stress induced into the channel layers during fabrication thereof. Dummy dielectric interposers may thus compensate for any source/drain stress/strain loss resulting from incorporating bottom source/drain isolation into source/drain structures. Transistors fabricated using dummy dielectric interposers and with source/drain bottom insulation have been observed to exhibit less performances losses than transistors fabricated using dummy semiconductor interposers and with source/drain bottom insulation.

Details of the proposed methods for fabricating multigate devices with bottom source/drain isolation (e.g., p-type GAA transistors) using dummy dielectric interposers are described herein in the following pages. From the description herein, it may be seen that multigate devices fabricated according to the methods described in the present disclosure offer advantages over multigate devices fabricated according to other methods, such as those using dummy semiconductor interposers. It is understood, however, that different embodiments may have different advantages, and no particular advantage is required of any embodiment.

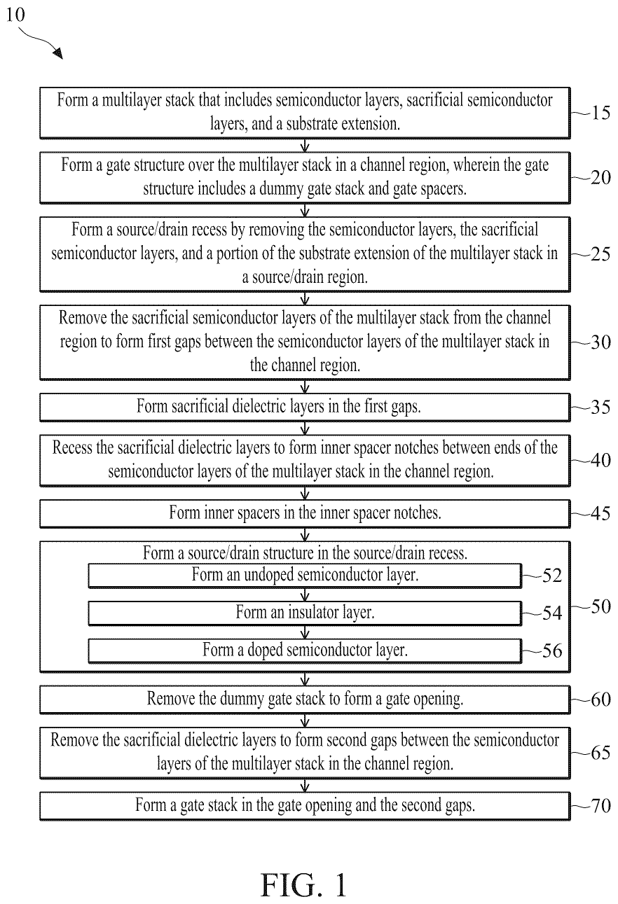

FIG. 1 is a flow chart of a method 10, in portion or entirety, for fabricating multigate devices (e.g., p-type transistors) using sacrificial dielectric layers (also referred to as dummy oxide interposers), according to various aspects of the present disclosure. At block 15, method 10 includes forming a multilayer stack that includes sacrificial semiconductor layers (e.g., silicon germanium layers), semiconductor layers (e.g., silicon layers), and a substrate extension. At block 20, a gate structure may be formed over the multilayer stack in a channel region. The gate structure may include a dummy gate stack and gate spacers. At block 35, a source/drain recess is formed by removing the semiconductor layers, the sacrificial semiconductor layers, and a portion of the substrate extension of the multilayer stack in a source/drain region. Method 10, at block 30, further includes removing the sacrificial semiconductor layers of the multilayer stack from the channel region to form first gaps between the semiconductor layers of the multilayer stack in the channel region. Sacrificial dielectric layers (e.g., oxide layers) are formed in the first gaps at block 35. Method 10 may further include recessing the sacrificial dielectric layers to form inner spacer notches between ends of the semiconductor layers of the multilayer stack in the channel region at block 40 and forming inner spacers in the inner spacer notches at block 45. At block 50, method 10 includes forming a source/drain structure in the source/drain recess, which may include forming an undoped semiconductor layer at block 52, forming an insulator layer at block 54, and forming a doped semiconductor layer at block 56. Method 10 may include removing the dummy gate stack to form a gate opening at block 60, removing the sacrificial dielectric layers to form second gaps between the semiconductor layers of the multilayer stack in the channel region at block 65, and forming a gate stack in the gate opening and the second gaps at block 70. Additional processing is contemplated by the present disclosure. Additional steps may be provided before, during, and after method 10, and some of the steps described may be moved, replaced, or eliminated for additional embodiments of method 10. The discussion that follows illustrates devices that may be fabricated according to method 10.

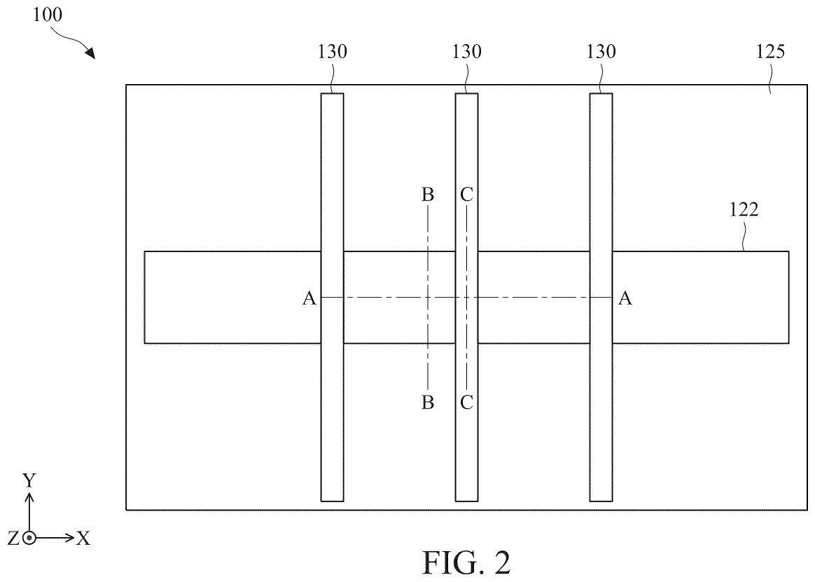

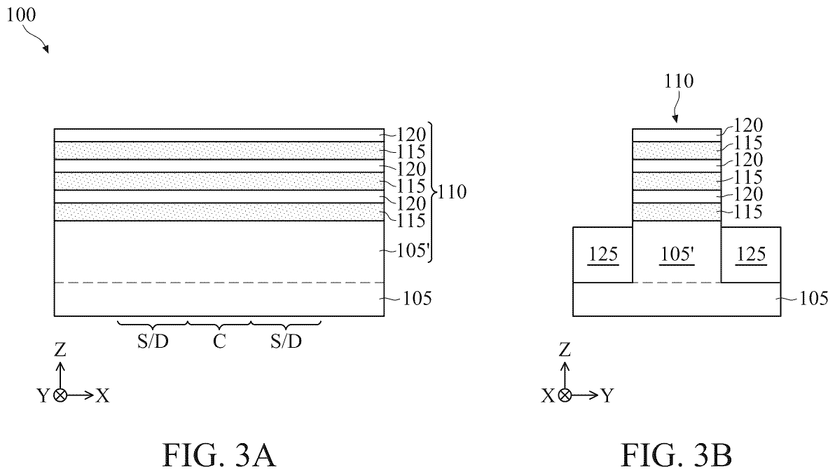

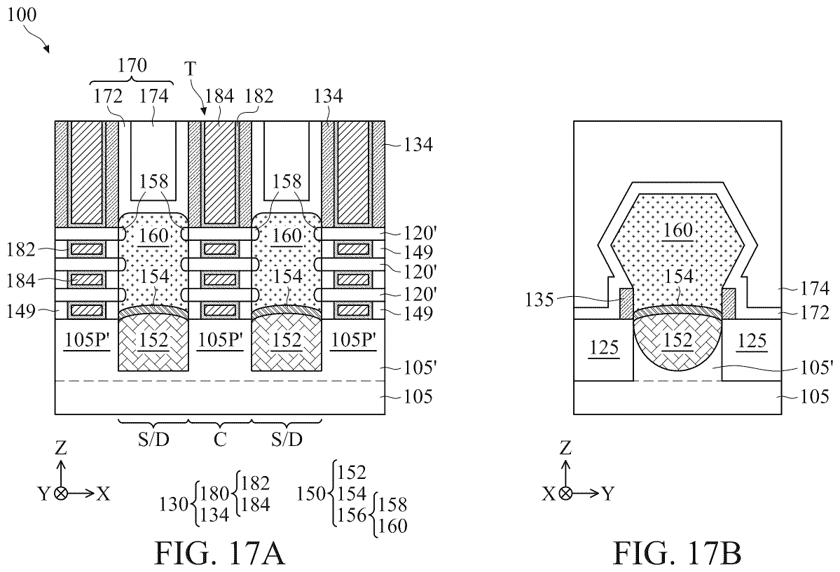

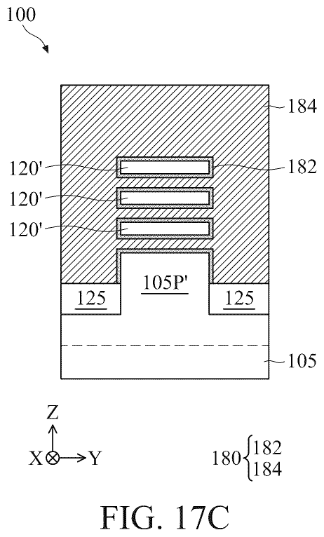

FIG. 2 is a top view of a device 100, in portion or entirety, that may be processed by method 10 of FIG. 1 to include bottom source/drain insulation, according to various aspects of the present disclosure. FIGS. 3A-19A are diagrammatic cross-sectional views of device 100, in portion or entirety, along line A-A of FIG. 2 at various stages of fabrication (such as those associated with method 10 of FIG. 1) according to various aspects of the present disclosure. FIGS. 3B-19B are diagrammatic cross-sectional views of device 100, in portion or entirety, along line B-B of FIG. 2 at various stages of fabrication (such as those associated with method 10 of FIG. 1) according to various aspects of the present disclosure. FIG. 17C is a cross-sectional view of device 100, in portion or entirety, along line C-C of FIG. 2 at the stage of fabrication of FIG. 17A and FIG. 17B, according to various aspects of the present disclosure. FIG. 2, FIGS. 3A-19A, FIGS. 3B-19B, and FIG. 17C are discussed concurrently herein for ease of description and understanding. FIG. 2, FIGS. 3A-19A, FIGS. 3B-19B, and FIG. 17C have been simplified for the sake of clarity to better understand the inventive concepts of the present disclosure. Additional features may be added in device 100, and some of the features described below may be replaced, modified, or eliminated in other embodiments of device 100.

After undergoing processing associated with FIG. 2, FIGS. 3A-19A, FIGS. 3B-19B, and FIG. 17C, device 100 may include at least one GAA transistor (i.e., a transistor having a gate that at least partially surrounds a suspended channel(s) (for example, a nanowire(s), a nanosheet(s), a nanobar(s), or the like) that extends between source/drains). In the depicted embodiment, device 100 is processed to fabricate p-type transistors having bottom source/drain insulation using dummy dielectric (e.g., oxide) interposers, which improves performance thereof. For example, p-type transistors fabricated as described herein may exhibit less leakage current, less parasitic capacitance, less channel resistance, less bottom source/drain insulation RO penalty, or combinations thereof than p-type transistors having bottom source/drain insulation fabricated using dummy semiconductor (e.g., SiGe) interposers. In some embodiments, device 100 is processed to form an n-type transistor. In some embodiments, device 100 is processed to form an n-type transistor and a p-type transistor. In such embodiments, device 100 may include a complementary metal-oxide semiconductor (CMOS) transistor. Device 100 may be included in a microprocessor, a memory, other IC device, or combinations thereof. In some embodiments, device 100 is a portion of an IC chip, a system on chip (SoC), or portion thereof, and device 100 may include various passive electronic devices and/or active electronic devices, such as resistors, capacitors, inductors, diodes, p-type field effect transistors (PFETs), n-type FETs (NFETs), metal-oxide-semiconductor FETs (MOSFETs), CMOS transistors, bipolar junction transistors (BJTs), laterally diffused MOS (LDMOS) transistors, high voltage transistors, high frequency transistors, other suitable components, or combinations thereof.

Referring to FIG. 2, FIG. 3A and FIG. 3B, fabrication of device 100 may include forming and/or receiving a device precursor, which may include a substrate 105 and a multilayer stack 110. Multilayer stack 110 may include sacrificial semiconductor layers 115 and semiconductor layers 120, and multilayer stack 110 may be disposed over a mesa (protrusion) 105′ of substrate 105. Multilayer stack 110 may correspond with and/or define an active region 122 of device 100. Active region 122 extends lengthwise along an x-direction (i.e., length is along the x-direction, width is along a y-direction, and height is along a z-direction), and active region 122 may be oriented substantially parallel to other active regions. Active region 122 may include channel regions (C), source regions, and drain regions. The source regions and the drain regions may collectively be referred to as source/drain regions (S/D).

Substrate 105 includes an elementary semiconductor, such as silicon and/or germanium; a compound semiconductor, such as silicon carbide, gallium arsenide, gallium phosphide, indium phosphide, indium arsenide, indium antimonide, or combinations thereof; an alloy semiconductor, such as SiGe, GaAsP, AlInAs, AlGaAs, GaInAs, GaInP, GaInAsP, or combinations thereof; or combinations thereof. In some embodiments, substrate 105 is a silicon substrate. In some embodiments, substrate 105 is a semiconductor-on-insulator substrate, such as a silicon-on-insulator (SOI) substrate, a silicon germanium-on-insulator (SGOI) substrate, or a germanium-on-insulator (GOI) substrate. Substrate 105 (and mesa 105′) may include various doped regions, such as p-type doped regions (e.g., p-wells), n-type doped regions (e.g., n-wells), or combinations thereof. N-type doped regions include n-type dopants, such as phosphorus, arsenic, other n-type dopant, or combinations thereof. P-type doped regions include p-type dopants, such as boron, indium, gallium, other p-type dopant, or combinations thereof. In some embodiments, the doped regions include p-type dopants and n-type dopants. The doped regions may be formed in substrate 105, mesas 105′, multilayer stack 110, or combinations thereof.

In some embodiments, multilayer stack 110 is formed by depositing sacrificial semiconductor layers 115 and semiconductor layers 120 over substrate 105 and patterning sacrificial semiconductor layers 115 and semiconductor layers 120. In some embodiments, the patterning is extended to substrate 105, thereby forming mesa 105′ thereof. Sacrificial semiconductor layers 115 and semiconductor layers 120 are stacked vertically (e.g., along the z-direction) in an interleaving and/or alternating configuration from a top of substrate 105. In some embodiments, the depositing includes epitaxially growing sacrificial semiconductor layers 115 and semiconductor layers 120 in the depicted interleaving/alternating configuration. For example, a first one of sacrificial semiconductor layers 115 is epitaxially grown on substrate 105, a first one of semiconductor layers 120 is epitaxially grown on the first one of sacrificial semiconductor layers 115, a second one of sacrificial semiconductor layers 115 is epitaxially grown on the first one of semiconductor layers 120, and so on until multilayer stack 110 has a desired number of sacrificial semiconductor layers 115 and semiconductor layers 120. In such embodiments, sacrificial semiconductor layers 115 and semiconductor layers 120 may be referred to as epitaxial layers. In some embodiments, epitaxial growth of sacrificial semiconductor layers 115 and semiconductor layers 120 is achieved by a molecular beam epitaxy (MBE) process, a chemical vapor deposition (CVD) process, a metalorganic (MOCVD) process, other suitable epitaxial growth process, or combinations thereof.

A composition of sacrificial semiconductor layers 115 is different than a composition of semiconductor layers 120 to achieve etch selectivity. For example, sacrificial semiconductor layers 115 and semiconductor layers 120 include different materials, constituent atomic percentages, constituent weight percentages, other characteristics, or combinations thereof to achieve etch selectivity. In some embodiments, sacrificial semiconductor layers 115 include silicon germanium, semiconductor layers 120 include silicon, and an etch rate of semiconductor layers 120 is different than an etch rate of sacrificial semiconductor layers 115 to a given etchant. In some embodiments, sacrificial semiconductor layers 115 and semiconductor layers 120 include the same material but with different constituent atomic percentages. For example, sacrificial semiconductor layers 115 and semiconductor layers 120 may include silicon germanium, and sacrificial semiconductor layers 115 and semiconductor layers 120 may have different germanium atomic percentages to provide etch selectivity. Sacrificial semiconductor layers 115 and semiconductor layers 120 may include any combination of materials that provides desired etching selectivity, desired oxidation rate differences, desired performance characteristics (e.g., materials that maximize current flow), or combinations thereof.

Semiconductor layers 120 or portions thereof may form channels of transistors. In the depicted embodiment, multilayer stack 110 includes three sacrificial semiconductor layers 115 and three semiconductor layers 120. Multilayer stack 110 thus includes three semiconductor layer pairs disposed over substrate 105, each of which has a respective sacrificial semiconductor layer 115 and a respective semiconductor layer 120. After processing of multilayer stack 110, this configuration may result in transistors having three channels. However, in some embodiments, multilayer stack 110 includes different numbers of semiconductor layers 120 depending, for example, on a number of channels desired for the transistors. For example, multilayer stack 110 may include two to six semiconductor layer pairs, each of which has a respective sacrificial semiconductor layer 115 and a respective semiconductor layer 120.

After patterning, multilayer stack 110 includes a semiconductor layer stack (i.e., sacrificial semiconductor layers 115 and semiconductor layers 120) disposed over mesa 105′ (also referred to as a substrate extension, a substrate fin portion, a fin portion, a protrusion, an etched substrate portion, etc.). Multilayer stack 110 may be referred to as a fin, a fin structure, a fin element, an active fin region, an active region, etc. In some embodiments, such as depicted, mesa 105′ may be considered a portion of multilayer stack 110. Multilayer stack 110 extends substantially along an x-direction, having a length along the x-direction, a width along a y-direction, and a height along a z-direction. In some embodiments, a lithography process and/or an etching process is performed to pattern sacrificial semiconductor layers 115, semiconductor layers 120, and substrate 105 to form multilayer stack 110. In some embodiments, multilayer stack 110 is formed by a multiple patterning process, such as a double patterning lithography (DPL) process (for example, a lithography-etch-lithography-etch (LELE) process, a self-aligned double patterning (SADP) process, a spacer-is-dielectric (SID) process, other double patterning process, or combinations thereof), a triple patterning process (for example, a lithography-etch-lithography-etch-lithography-etch (LELELE) process, a self-aligned triple patterning (SATP) process, other triple patterning process, or combinations thereof), other multiple patterning process (for example, self-aligned quadruple patterning (SAQP) process), or combinations thereof. In some embodiments, directed self-assembly (DSA) techniques are implemented. In some embodiments, multilayer stack 110 is formed by a fin fabrication process.

Substrate isolation structures 125 may be formed adjacent to and around a lower portion of multilayer stack 110 (e.g., mesas 105′ thereof), and multilayer stack 110 may be separated from other multilayer stacks and/or other device regions by substrate isolation structures 125. Substrate isolation structures 125 may electrically isolate an active device region (e.g., multilayer stack 110) from other device regions, such as other multilayer stacks. Substrate isolation structures 125 include silicon oxide, silicon nitride, silicon oxynitride, other suitable isolation material (including, silicon, oxygen, nitrogen, carbon, other suitable isolation constituent, or combinations thereof), or combinations thereof. Substrate isolation structures 125 may have a multilayer structure. For example, substrate isolation structures 125 may include a bulk dielectric (e.g., an oxide layer) over a dielectric liner (e.g., silicon nitride, silicon oxide, silicon oxynitride, silicon oxycarbonitride, or combinations thereof). In another example, substrate isolation structures 125 may include a bulk dielectric over a doped liner, such as a boron silicate glass (BSG) liner and/or a phosphosilicate glass (PSG) liner. Dimensions and/or characteristics of substrate isolation structures 125 may be configured to provide shallow trench isolation (STI) structures, deep trench isolation (DTI) structures, local oxidation of silicon (LOCOS) structures, other suitable isolation structures, or combinations thereof.

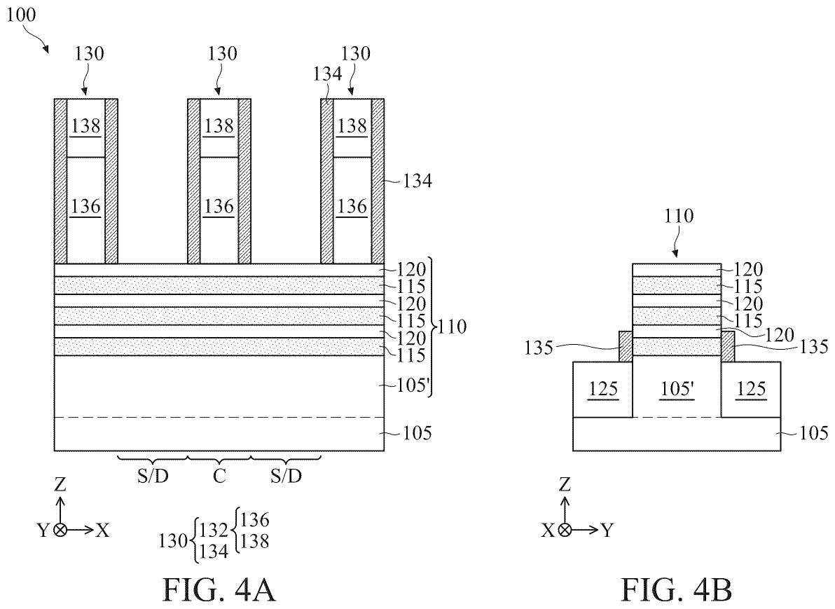

Referring to FIG. 4A and FIG. 4B, gate structures 130 may be formed over channel regions (C) of active region 122 and between respective source/drain regions (S/D) of active region 122. Each gate structure 130 may include a respective dummy gate stack 132 and respective gate spacers 134. Dummy gate stacks 132 extend lengthwise along a direction different than (e.g., orthogonal to) the lengthwise direction of multilayer stack 110. For example, dummy gate stacks 132 extend along the y-direction, having a length along the y-direction, a width along the x-direction, and a height along the z-direction. Dummy gate stacks 132 may extend substantially parallel to one another. In FIG. 4A (e.g., a cross-sectional view along the gate widthwise direction), dummy gate stacks 132 are disposed on top of respective channel regions, and dummy gate stacks 132 are disposed between respective source/drain regions. In a cross-sectional view along the gate lengthwise direction, dummy gate stacks 132 may wrap respective channel regions (e.g., be disposed over the top and sidewalls thereof), and dummy gate stacks 132 may be disposed over tops of substrate isolation structures 125.

Each dummy gate stack 132 may include a dummy gate 136 and a hard mask 138. In some embodiments, dummy gates 136 include a dummy gate dielectric and a dummy gate electrode. The dummy gate dielectric includes a dielectric material, such as silicon oxide and/or other suitable dielectric material. The dummy gate electrode includes a suitable dummy gate material, such as polysilicon. In some embodiments, forming dummy gate stacks 132 includes depositing a dummy gate dielectric layer over multilayer stack 110, depositing a dummy gate electrode layer over the dummy gate dielectric layer, and depositing a hard mask layer over the dummy gate electrode layer. One or more lithography and etching processes may then be performed to pattern the hard mask layer, the dummy gate electrode layer, and the dummy gate dielectric layer, and remainders of the hard mask layer, the dummy gate electrode layer, and the dummy gate dielectric layer may form the dummy gate dielectrics, the dummy gate electrodes, and the hard masks, respectively, of dummy gate stacks 132, such as depicted.

Gate spacers 134 are then formed adjacent to and along sidewalls of dummy gate stacks 132. In some embodiments, fin spacers 135 are formed adjacent to and along sidewalls of multilayer stack 110 in source/drain regions, such as a depicted in FIG. 4B. Gate spacers 134 and fin spacers 135 may be formed by any suitable process, and in some embodiments, gate spacers 134 and fin spacers 135 are formed simultaneously. Gate spacers 134 and fin spacers 135 include a dielectric material, which may include silicon, oxygen, carbon, nitrogen, other suitable dielectric constituent, or combinations thereof (e.g., silicon oxide, silicon nitride, silicon oxynitride, silicon carbide, silicon carbonitride, silicon oxycarbide, silicon oxycarbonitride, or combinations thereof). In some embodiments, gate spacers 134 and/or fin spacers 135 have a multilayer structure, such as two or more dielectric layers having different compositions. In some embodiments, gate spacers 134 include more than one set of spacers, such as seal spacers, offset spacers, sacrificial spacers, dummy spacers, main spacers, or combinations thereof. In such embodiments, the various sets of spacers may have different compositions.

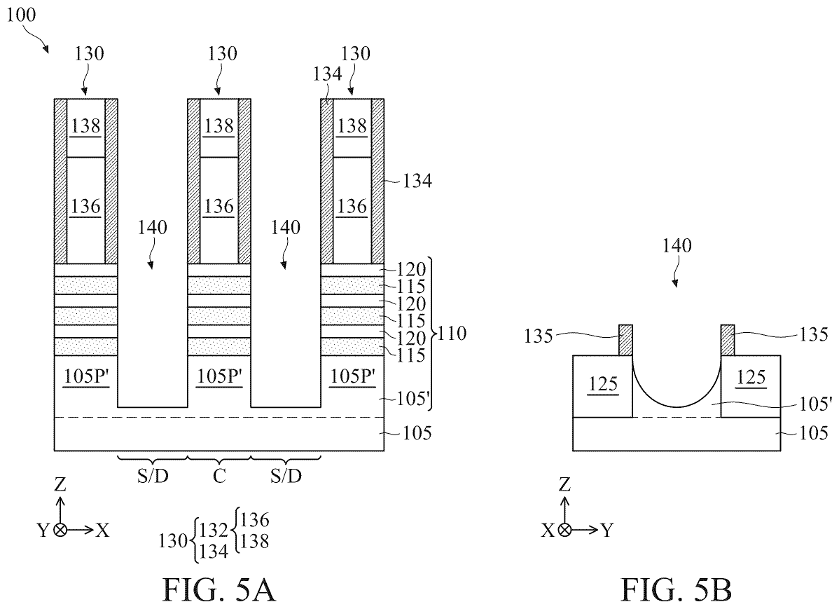

Referring to FIG. 5A and FIG. 5B, a source/drain etch removes portions of multilayer stack 110 that are not covered by gate structures 130, thereby forming source/drain recesses (trenches) 140. For example, the source/drain etch removes semiconductor layers 120 and sacrificial semiconductor layers 115 in source/drain regions, thereby exposing mesa 105′ therein. The source/drain etch may further remove some, but not all, of mesa 105′ in source/drain regions, such that source/drain recesses 140 extend into but not through mesa 105′. After the source/drain etch, sacrificial semiconductor layers 115, semiconductor layers 120, and projecting portions formed from mesa 105′ (referred to hereafter as mesas 105P′) remain in channel regions, and source/drain recesses 140 expose sidewalls of sacrificial semiconductor layers 115, semiconductor layers 120, and mesas 105P′ remaining in channel regions. The source/drain etch is a dry etch, a wet etch, other suitable etch, or combinations thereof. In some embodiments, the source/drain etch is a multistep etch process, which may alternate etchants to remove sacrificial semiconductor layers 115 and semiconductor layers 120 separately and alternately. In some embodiments, source/drain etch parameters (e.g., etchant thereof) are tuned to selectively remove semiconductor materials (e.g., semiconductor layers 120, sacrificial semiconductor layers 115, and mesa 105′) with negligible (to no) removal of dielectric materials (e.g., dummy gate stacks 132, gate spacers 134, fin spacers 135, substrate isolation structures 125, etc.).

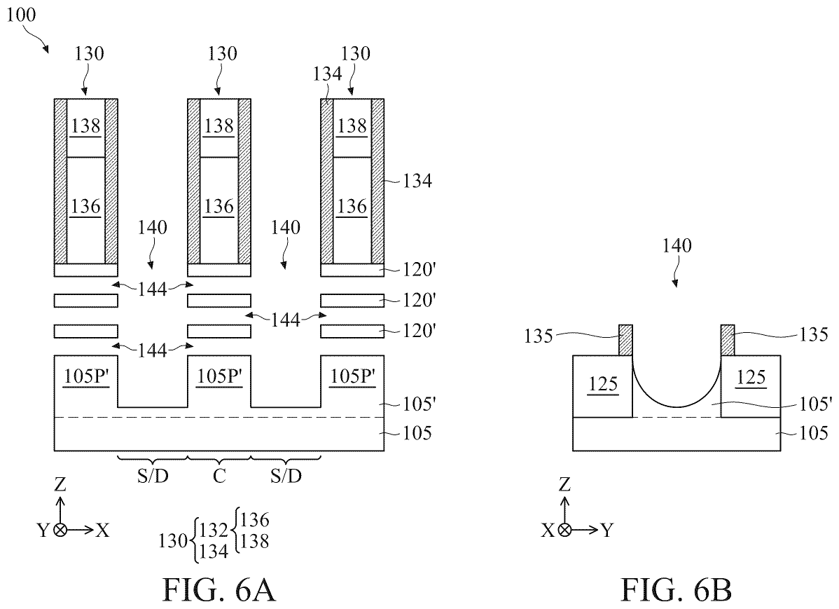

Referring to FIGS. 6A-8A and FIGS. 6B-8B, sacrificial semiconductor layers 115 are replaced with sacrificial oxide layers 146. Referring to FIG. 6A and FIG. 6B, an etching process selectively removes sacrificial semiconductor layers 115 exposed by source/drain recesses 140, thereby forming gaps 144 in channel regions. The etching process may selectively remove sacrificial semiconductor layers 115 with respect to substrate 105, semiconductor layers 120, dummy gate stacks 132 (e.g., hard masks 138 thereof), gate spacers 134, fin spacers 135, or combinations thereof. In other words, the etching process removes sacrificial semiconductor layers 115 with negligible (to no) removal of substrate 105, semiconductor layers 120, dummy gate stacks 132 (e.g., hard masks thereof), gate spacers 134, fin spacers 135, or combinations thereof. In some embodiments, an etchant is selected for the etching process that etches silicon germanium (e.g., sacrificial semiconductor layers 115) at a higher rate than silicon (e.g., semiconductor layers 120 and mesa 105′) and dielectric materials (e.g., gate spacers 134, fin spacers 135, and hard masks 138 of dummy gate stacks 132). The etching process is a dry etch, a wet etch, other suitable etch, or combinations thereof. In some embodiments, before the etching process, an oxidation process may be performed to convert sacrificial semiconductor layers 115 into semiconductor oxide layers (e.g., silicon germanium oxide layers). In such embodiments, the etching process removes semiconductor oxide layers to form gaps 144.

Semiconductor layers 120 remaining in channel regions are suspended over mesas 105P′ after removing sacrificial semiconductor layers 115. In the depicted embodiment, each channel region has three suspended semiconductor layers 120, which are referred to hereafter as channel layers 120′. Channel layers 120′ are vertically stacked along the z-direction, and channel layers 120′ may provide three channels through which current can flow between respective, subsequently formed source/drains. In some embodiments, after removing sacrificial semiconductor layers 115, an etching process may be performed to modify a profile of channel layers 120′ to provide target dimensions and/or target shapes thereof. For example, the etching process may provide channel layers 120′ with cylindrical-shaped profiles (e.g., nanowires), rectangular-shaped profiles (e.g., nanobars), sheet-shaped profiles (e.g., nanosheets), or any other suitable shaped profile. In some embodiments, channel layers 120′ have nanometer-sized dimensions and may be referred to as “nanostructures.” In some embodiments, channel layers 120′ have sub-nanometer dimensions and/or other suitable dimensions.

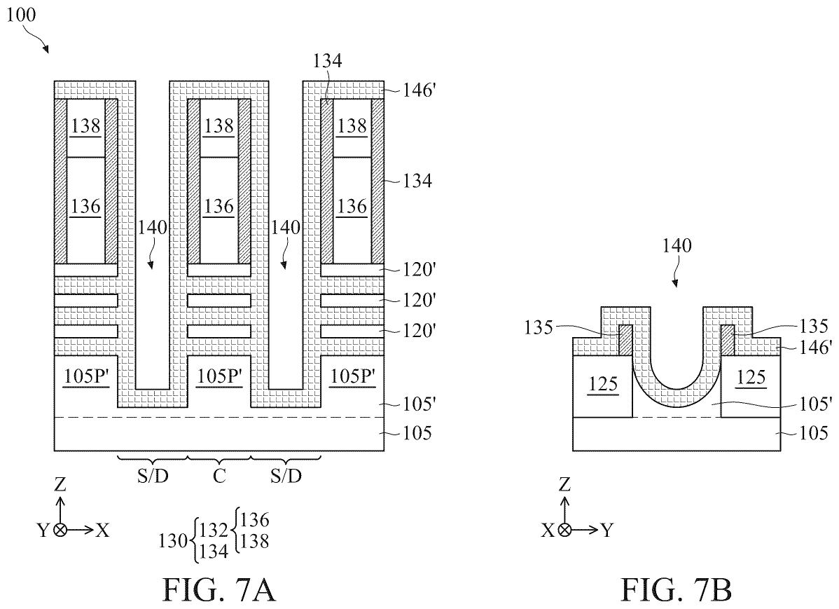

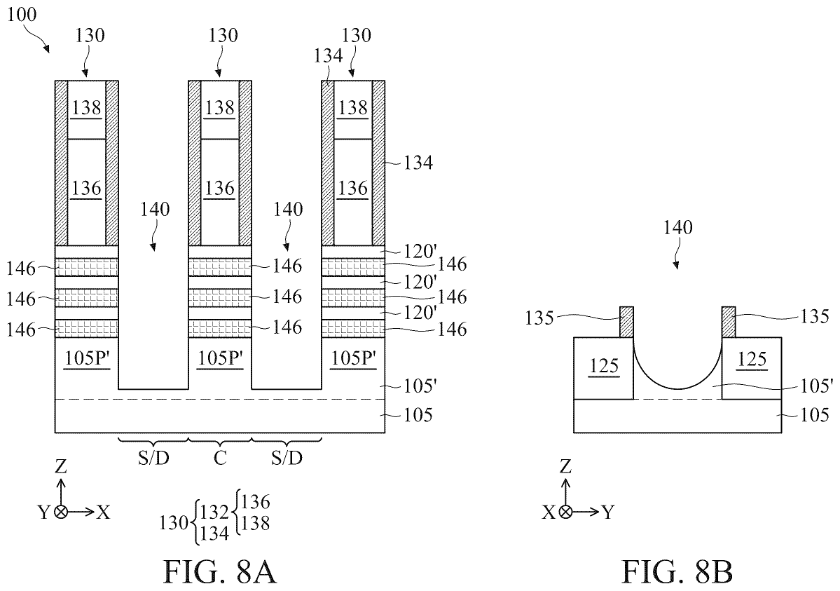

Referring to FIG. 7A (and FIG. 7B) and FIG. 8A (and FIG. 8B), sacrificial oxide layers 146 are formed in gaps 144. Sacrificial oxide layers 146 include oxygen and silicon, carbon, nitrogen, other suitable constituent, or combinations thereof. For example, sacrificial oxide layers 146 include oxygen and silicon, and sacrificial oxide layers 146 are silicon oxide layers. In some embodiments, sacrificial oxide layers 146 are formed by depositing an oxide layer 146′ over device 100 (e.g., FIG. 7A and FIG. 7B) and etching oxide layer 146′, such that oxide layer 146′ is removed from source/drain regions, but not channel regions, of device 100 (e.g., FIG. 8A and FIG. 8B). Referring to FIG. 7A and FIG. 7B, as-deposited oxide layer 146′ fills gaps 144, partially fills source/drain recesses 140, and lines source/drain recesses 140. As-deposited oxide layer 146′ may further be disposed over gate structures 130, substrate isolation structures 125, fin spacers 135, other features of device 100, or combinations thereof. Oxide layer 146′ is formed by flowable chemical vapor deposition (FCVD), atomic layer deposition (ALD), plasma enhanced chemical vapor deposition (PECVD), other deposition process, or combinations thereof. In some embodiments, sacrificial oxide layers 146 have multilayer structures, such as a first oxide layer and a second oxide layer. The first oxide layer and the second oxide layer may be formed of a same material (e.g., silicon oxide), but formed by different deposition processes. For example, the first oxide layer may be formed by ALD, and the second oxide layer may be formed over the first oxide layer by FCVD. In some embodiments, the first oxide layer and the second oxide layer are formed of different oxide materials by the same type of deposition processes or different type of deposition processes.

Referring to FIG. 8A and FIG. 8B, an etching process removes exposed portions of oxide layer 146′ (e.g., those not filling gaps 144). For example, the etching process may remove portions of oxide layer 146′ disposed on sidewalls of channel layers 120′, sidewalls of mesas 105P′, surfaces of mesa 105′ that form bottoms of source/drain recesses 140, tops and sidewalls of fin spacers 135, tops and sidewalls of gate spacers 134, tops of dummy gate stacks 132, and tops of substrate isolation structures 125. Remainders of oxide layer 146′ provide sacrificial oxide layers 146 in the channel regions. The etching process selectively removes oxide layer 146′ with respect to substrate 105, channel layers 120′, dummy gate stacks 132 (e.g., hard masks 138 thereof), gate spacers 134, fin spacers 135, substrate isolation structures 125, or combinations thereof. In other words, the etching process removes oxide layer 146′ with negligible (to no) removal of substrate 105, channel layers 120′, dummy gate stacks 132 gate spacers 134, fin spacers 135, substrate isolation structures 125, or combinations thereof. In some embodiments, an etchant is selected that etches an oxide material (e.g., oxide layer 146′) at a higher rate than silicon (e.g., channel layers 120′ and mesa 105′), dielectric materials different than the oxide material (e.g., gate spacers 134, fin spacers 135, hard masks 138, etc.). The etching process is a dry etch, a wet etch, other suitable etch, or combinations thereof.

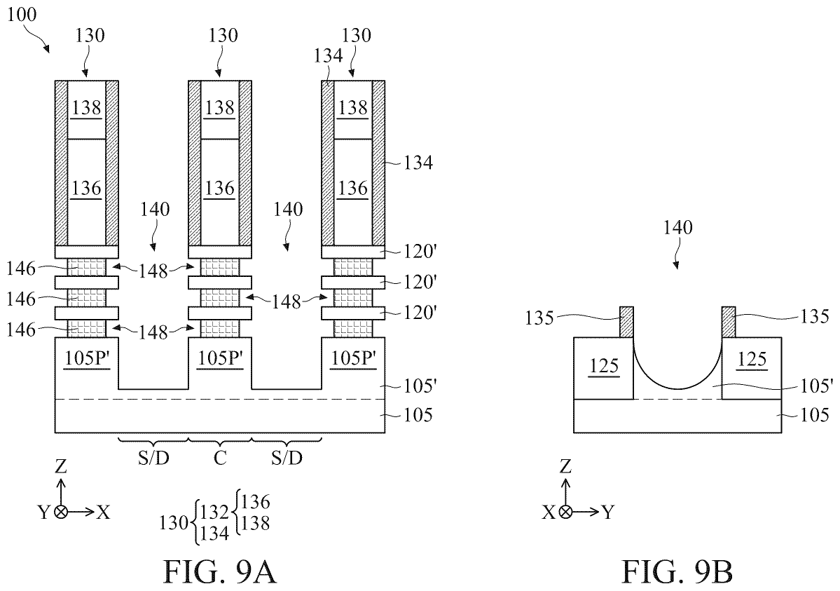

Referring to FIG. 9A and FIG. 9B, an etching process (e.g., an anisotropic etch) laterally recesses sacrificial oxide layers 146 to form notches 148 under gate structures 130 (e.g., under gate spacers 134 thereof). For example, the etching process may laterally etch (e.g., along the x-direction and/or the y-direction) sacrificial oxide layers 146 to reduce their lengths along the x-direction, such that lengths of sacrificial oxide layers 146 are less than lengths of channel layers 120′. Sacrificial oxide layers 146 may be removed from ends of channel layers 120′, thereby exposing tops and bottoms of ends of channel layers 120′. In some embodiments, notches 148 laterally extend (e.g., along the x-direction) under dummy gate stacks 132. In some embodiments, the etching process may recess substrate isolation structures 125. In such embodiments, substrate isolation structures 125 may have curved (e.g., concave) top surfaces.

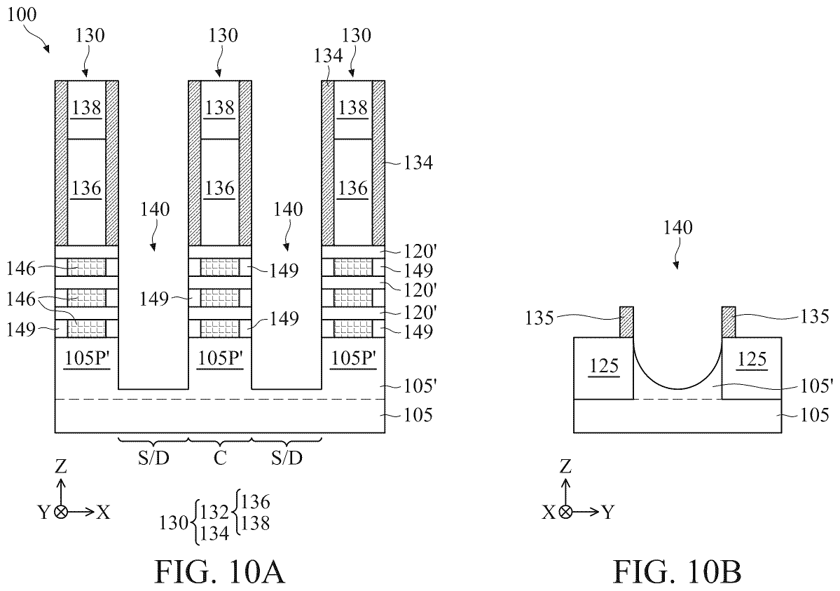

Referring to FIG. 10A and FIG. 10B, inner spacers 149 are formed in notches 148, and remainders of sacrificial oxide layers 146 are disposed between respective inner spacers 149. Inner spacers 149 may replace ends of sacrificial oxide layers 146. Inner spacers 149 are disposed under gate spacers 134 along sidewalls of sacrificial oxide layers 146. Further, inner spacers 149 are disposed between ends of respective semiconductor layers 120, and bottom inner spacers 149 are disposed between ends of respective bottom semiconductor layers 120 and respective mesas 105P′. Inner spacers 149 may be formed by an inner spacer deposition and an inner spacer etch. The inner spacer deposition forms an inner spacer layer over device 100 that at least partially fills notches 148. In some embodiments, a single deposition process is performed to form an inner spacer layer that fills notches 148. In some embodiments, inner spacers 149 have multilayer structures, and the inner spacer deposition includes more than one deposition process to form a multilayer inner spacer layer, such as a first deposition process to form a first inner spacer sublayer and a second deposition process to form a second inner spacer sublayer. The first inner spacer sublayer partially fills notches 148, and the second inner spacer sublayer may partially or completely fill notches 148. A composition of the first inner spacer sublayer is the same or different than a composition of the second inner spacer sublayer.

The inner spacer etch may selectively etch the inner spacer layer with negligible (to no) etching of channel layers 120′, mesas 105P′, dummy gate stacks 132 (e.g., hard masks 138 thereof), gate spacers 134, fin spacers 135, substrate isolation structures 125, or combinations thereof. Remainders of the inner spacer layer provide inner spacers 149, such as depicted. To achieve desired etching selectivity, the inner spacer layer (and thus inner spacers 149) have a composition different than compositions of channel layers 120′, mesas 105P′, dummy gate stacks 132, gate spacers 134, fin spacers 135, substrate isolation structures 125, or combinations thereof. In some embodiments, the inner spacer layer includes a dielectric material that includes silicon, oxygen, carbon, nitrogen, other suitable dielectric constituent, or combinations thereof. For example, the inner spacer layer may be a silicon carbide layer, a silicon carbonitride layer, a silicon oxycarbonitride layer, a silicon oxycarbide layer, or combinations thereof. The inner spacer etch is a dry etch, a wet etch, other suitable etch, or combinations thereof. In some embodiments, parameters of the inner spacer deposition and/or the inner spacer etch are configured and/or tuned to provide inner spacers 149 with air gaps. In some embodiments, device 100 does not include inner spacers 149. In such embodiments, processing of device 100 associated with FIG. 9A, FIG. 9B, FIG. 10A, and FIG. 10B may be omitted.

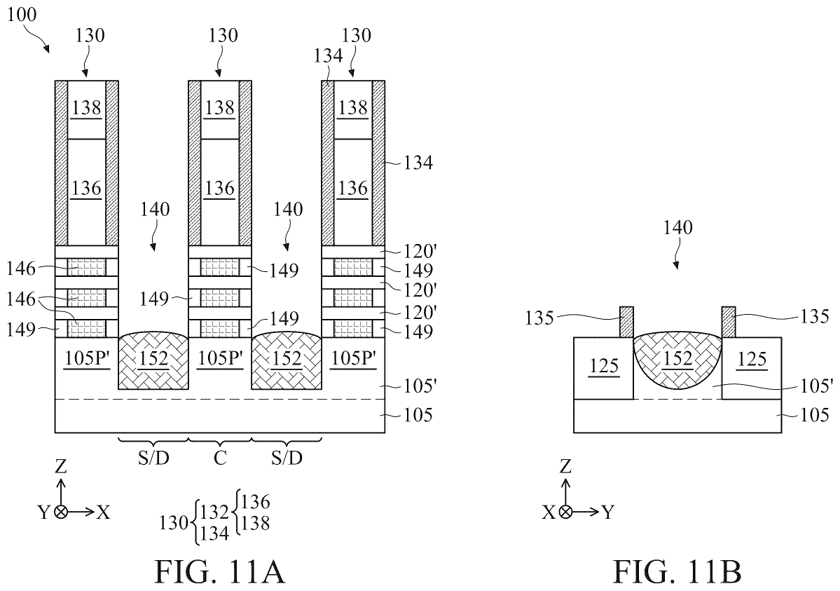

Referring to FIGS. 11A-13A and FIGS. 11B-13B, source/drain structures 150 are formed in source/drain recesses 140. Each source/drain structure 150 may include an undoped semiconductor layer 152, an insulator layer 154, and a doped semiconductor layer 156. In some embodiments, doped semiconductor layers 156 have a multilayer structure. For example, each doped semiconductor layer 156 may include a doped semiconductor layer 158 and a doped semiconductor layer 160. In some embodiments, source/drain structures 150 form source/drains of p-type transistors, and source/drain structures 150 may include semiconductor material(s) doped with p-type dopant (e.g., boron, gallium, other p-type dopant, or combinations thereof). In some embodiments, source/drain structures 150 form source/drains of n-type transistors, and source/drain structures 150 may include semiconductor material(s) doped with n-type dopant (e.g., carbon, phosphorous, arsenic, antimony, other n-type dopant, or combinations thereof). As used herein, source/drain, source/drain region, source/drain structure, source/drain feature, epitaxial source/drain, epitaxial source/drain feature, etc. may refer to a source of device 100, a drain of device 100, or a source and/or a drain of multiple devices (including device 100).

Referring to FIG. 11A and FIG. 11B, semiconductor layers, such as undoped semiconductor layers 152, may be formed in source/drain recesses 140. Undoped semiconductor layers 152 may be formed in bottoms of source/drain recesses 140. Undoped semiconductor layers 152 are disposed below bottommost channel layers 120′ (e.g., below bottoms thereof). In the depicted embodiment, undoped semiconductor layers 152 extend slightly above top surfaces of mesas 105P′. In some embodiments, top surfaces of undoped semiconductor layers 152 are substantially level with or below top surfaces of mesas 105P′ (i.e., undoped semiconductor layers 152 do not extend beyond top surfaces of mesas 105P′). Undoped semiconductor layers 152 are dopant-free (i.e., substantially free of n-type dopants and p-type dopants). For example, no intentional doping is performed when forming undoped semiconductor layers 152. Undoped semiconductor layers 152 may provide high resistance paths at bottoms of source/drains, thereby suppressing leakage current into substrate 105/mesas 105P′. Undoped semiconductor layers 152 include silicon, germanium, silicon germanium, other suitable semiconductor materials, or combinations thereof. In the depicted embodiment, undoped semiconductor layers 152 are dopant-free silicon germanium layers. In some embodiments, undoped semiconductor layers 152 are dopant-free silicon layers. In some embodiments, semiconductor materials (e.g., SiGe) having dopant concentrations less than about 5×10¹⁸ cm⁻³ (e.g., about 1×10¹⁸ cm⁻³ to about 5×10¹⁸ cm⁻³) may be considered undoped and/or unintentionally doped (UID).

Undoped semiconductor layers 152 may be deposited on and/or grown from substrate 105, mesa 105′, mesas 105P′, or combinations thereof. In some embodiments, undoped semiconductor layers 152 are formed by a selective epitaxial growth (SEG) process, which may selectively deposit/grow semiconductor material (e.g., silicon germanium) on/from exposed semiconductor surfaces. Undoped semiconductor layers 152 may thus be referred to as undoped epitaxial layers. The SEG process may use chemical vapor deposition (CVD) techniques (e.g., vapor-phase epitaxy (VPE), ultra-high vacuum CVD (UHV-CVD), low pressure CVD (LPCVD), PECVD, or the like), molecular beam epitaxy, other suitable epitaxial growth process, or combinations thereof. In some embodiments, undoped semiconductor layers 152 are formed by a bottom-up deposition process, such that semiconductor material is deposited on mesas 105P′, mesa 105′, and/or substrate 105 (i.e., in bottoms of source/drain recesses 140) with minimal (to no) deposition of semiconductor material on channel layers 120′. In some embodiments, an etching process may be performed after the bottom-up deposition process to remove any semiconductor material that may have formed on channel layers 120′. The post-deposition etch may be a dry etch, a wet etch, other suitable etch, or combinations thereof.

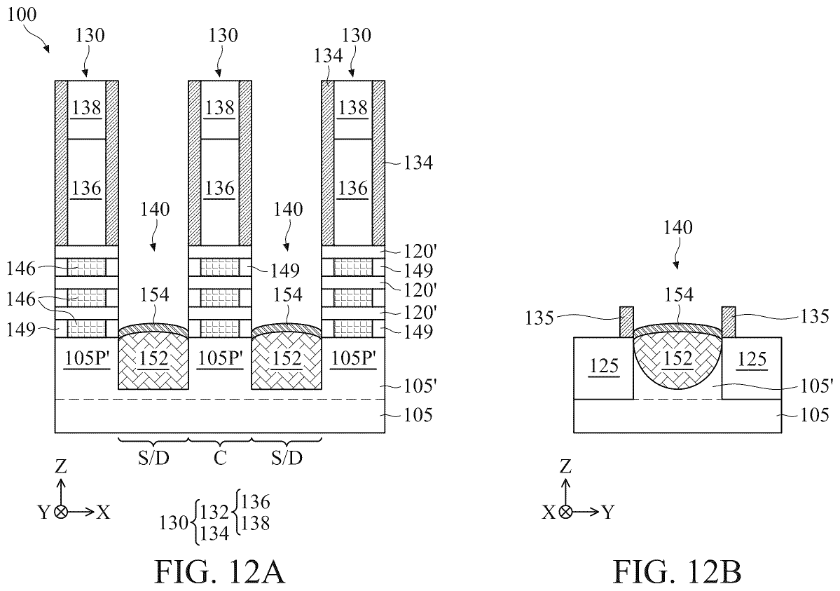

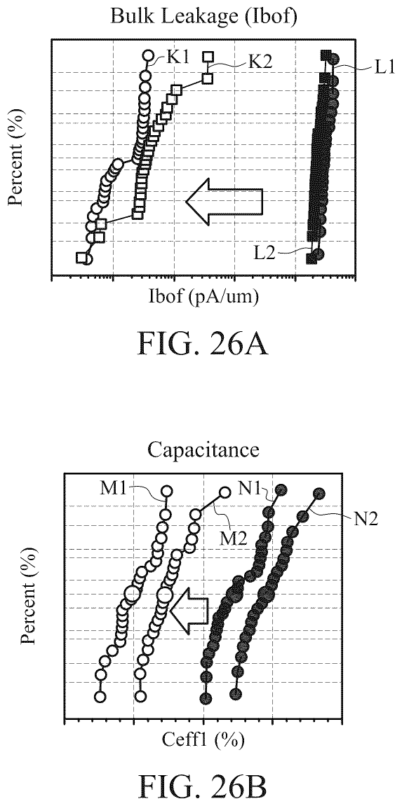

Referring to FIG. 12A and FIG. 12B, insulator layers 154 may be formed in source/drain recesses 140 over undoped semiconductor layers 152. Insulator layers 154 partially fill source/drain recesses 140, and insulator layers 154 are disposed below bottommost channel layers 120′ (e.g., below bottoms thereof). Insulator layers 154 may be disposed on bottommost inner spacers 149 and/or mesas 105P′, such as depicted. Insulator layers 154 include an electrically insulating material, such as a dielectric material, that may reduce unwanted leakage current, such as current that may undesirably flow between doped semiconductor layers 156 through mesas 105P′. For example, referring to FIG. 26A, devices having source/drain structures with bottom source/drain insulation (e.g., insulator layers 154) (corresponding with line K1 and line K2) have been observed to exhibit less bulk leakage current (I_{boff}) than devices having source/drain structures without bottom source/drain insulation (e.g., free of insulator layers 154) (corresponding with line L1 and line L2). Further, referring to FIG. 26B, devices having source/drain structures with bottom source/drain insulation (corresponding with line M1 and line M2) have also been observed to exhibit less capacitance (C_{eff}) than devices having source/drain structures without bottom source/drain insulation (corresponding with line N1 and line N2). In some embodiments, insulator layers 154 include a silicon-comprising dielectric material, such as silicon nitride, silicon oxynitride, silicon oxycarbonitride, silicon oxycarbide, silicon carbonitride, other silicon-comprising dielectric material (which may include silicon and nitrogen, carbon, oxygen, other suitable dielectric constituent, or combinations thereof), or combinations thereof. For example, in the depicted embodiment, insulator layers 154 are silicon nitride layers. In some embodiments, insulator layers 154 include a metal-comprising dielectric material, such as a metal oxide material and/or a metal nitride material.

Insulator layers 154 may be formed by depositing an insulator material over device 100 (e.g., by CVD, physical vapor deposition (PVD), other suitable process, or combinations thereof) and etching the insulator material, such that remainders of the insulator material are disposed over undoped semiconductor layers 152. The as-deposited insulator material may be disposed on tops of gate structures 130 (e.g., tops of gate spacers 134 and dummy gate stacks 132), sidewalls of gate structures 130 (e.g., of gate spacers 134), sidewalls of channel layers 120′, sidewalls of inner spacers 149, and sidewalls of mesas 105P′. In some embodiments, as a result of properties of a deposition process, a thickness of the insulator material over horizontally oriented surfaces (e.g., tops of undoped semiconductor layers 152 and tops of gate structures 130) may be greater than a thickness of the insulator material over vertically oriented surfaces (e.g., sidewalls of gate structures 130, sidewalls of channel layers 120′, and sidewalls of inner spacers 149). Parameters of the etching may thus be tuned to remove vertically oriented portions of the insulator material, such as that on sidewalls of gate structures 130, sidewalls of channel layers 120′, and sidewalls of inner spacers 149. In such embodiments, as a result of etch loading effects, the etching may also remove horizontally oriented portions of the insulator material on top of gate structures 130, but not (or minimally) horizontally oriented portions and/or vertically oriented portions of the insulator material in bottoms of source/drain recesses 140, such as that disposed on undoped semiconductor layers 152 (i.e., the etching process may thin such portions). In some embodiments, the as-deposited insulator material fills source/drain recesses 140 and the etching recesses the insulator material at least to bottom sacrificial oxide layers 146. The etching may be a dry etch, a wet etch, other suitable etch, or combinations thereof.

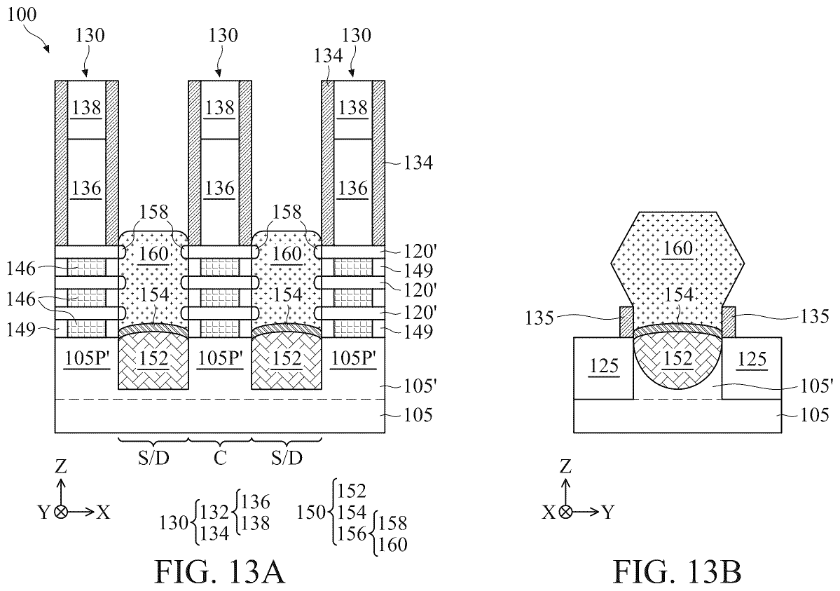

Referring to FIG. 13A and FIG. 13B, doped semiconductor layers 156 may be formed in source/drain recesses 140 over insulator layers 154 and/or undoped semiconductor layers 152. Doped semiconductor layers 156 fill remainders of source/drain recesses 140, and doped semiconductor layers 156 are coupled to edges/ends of channel layers 120′. In the depicted embodiment, doped semiconductor layers 156 include doped semiconductor layers 158 and doped semiconductor layers 160. Doped semiconductor layers 158 may be formed over channel layers 120′ and partially fill source/drain recesses 140, and doped semiconductor layers 160 may be formed over doped semiconductor layers 158 and/or insulator layers 154 and fill remainders of source/drain recesses 140. Doped semiconductor layers 158 are between channel layers 120′ and doped semiconductor layers 160, and insulator layers 154 are between doped semiconductor layers 160 and undoped epitaxial layers 152. In the depicted embodiment, doped semiconductor layers 158 are discontinuous and formed of discrete and separate portions, each of which is disposed on an end of a respective channel layer 120′ (i.e., portions of doped semiconductor layers 158 disposed on adjacent channel layers 120′ are not connected to one another). In such embodiments, doped semiconductor layers 160 may wrap doped semiconductor layers 158 and/or doped semiconductor layers 160 may extend to and be disposed on inner spacers 149. In some embodiments, one or more of the discrete, separate portions of doped semiconductor layers 158 may wrap a respective channel layer 120′, such that the discrete, separate portions are formed over a top and/or a bottom of the respective channel layer 120′. In some embodiments, the discrete, separate portions extend over and/or to inner spacers 149. In some embodiments, one or more of the discrete, separate portions of doped semiconductor layers 158 are connected. In such embodiments, portions of doped semiconductor layers 160 may be separated from inner spacers 149 by doped semiconductor layers 158. In some embodiments, doped semiconductor layers 158 wrap doped semiconductor layers 160, and doped semiconductor layers 158 are further between inner spacers 149 and doped semiconductor layers 160.

Doped semiconductor layers 158 and doped semiconductor layers 160 include silicon, germanium, silicon germanium, other suitable semiconductor materials, or combinations thereof. In some embodiments, doped semiconductor layers 158 and doped semiconductor layers 160 include the same semiconductor material with different constituent concentrations. For example, doped semiconductor layers 158 and doped semiconductor layers 160 may include silicon germanium and p-type dopant (e.g., boron and/or gallium), but different germanium concentrations and/or different p-type dopant concentrations, such as where source/drain structures 150 belong to p-type transistors. In such example, doped semiconductor layers 158 may have a smaller germanium concentration (e.g., Ge %) and/or a smaller p-type dopant concentration (e.g., B %) than doped semiconductor layers 160. In other words, doped semiconductor layers 160 may be heavily doped semiconductor layers, and doped semiconductor layers 158 may be lightly doped semiconductor layers. In another example, doped semiconductor layers 158 and doped semiconductor layers 160 may include silicon and n-type dopant (e.g., phosphorous and/or arsenic), but different n-type dopant concentrations, such as where source/drain structures 150 belong to n-type transistors. In such example, doped semiconductor layers 158 may have a smaller n-type dopant concentration (e.g., P %) than doped semiconductor layers 160. In some embodiments, doped semiconductor layers 158 and doped semiconductor layers 160 have different semiconductor material with the same or different constituent concentrations. In some embodiments, doped semiconductor layers 156 include materials and/or dopants that provide compressive stress in channel layers 120′, such as where source/drain structures 150 belong to p-type transistors. In some embodiments, doped semiconductor layers 156 include materials and/or dopants that provide tensile stress in channel layers 120′, such as where source/drain structures 150 belong to n-type transistors.

Doped semiconductor layers 158 may be deposited on and/or grown from channel layers 120′, and doped semiconductor layers 160 may be deposited on and/or grown from doped semiconductor layers 158. In some embodiments, doped semiconductor layers 158 and doped semiconductor layers 160 are formed by respective SEG processes, which may implement CVD deposition techniques (e.g., VPE, UHV-CVD, LPCVD, PECVD, or the like), molecular beam epitaxy, other suitable SEG process, or combinations thereof. The SEG processes may use gaseous and/or liquid precursors that interact with the composition of channel layers 120′, doped semiconductor layers 158, or combinations thereof. Epitaxial growth/deposition conditions, such as those described herein, are tuned to selectively deposit (grow) semiconductor material (e.g., silicon germanium) on semiconductor surfaces (e.g., channel layers 120′ and/or doped semiconductor layers 158) while limiting (or preventing) growth of semiconductor material from dielectric surfaces and/or non-semiconductor surfaces (e.g., inner spacers 149, dummy gate stacks 132, gate spacers 134, fin spacers 135, substrate isolation structures 125, or combinations thereof). In some embodiments, doped semiconductor layers 158 and/or doped semiconductor layers 160 are doped during deposition (i.e., in-situ doping), such as by adding dopants to a source material of the SEG processes. In some embodiments, doped semiconductor layers 158 and/or doped semiconductor layers 160 are doped after deposition, such as by an ion implantation process. In some embodiments, annealing is performed to activate dopants in doped semiconductor layers 158, doped semiconductor layers 160, other source/drain regions/features, such as source/drain junction implants, or combinations thereof. Fabrication of source/drain structures 150 may be configured to provide source/drain structures 150 with various dimensions. For example, in some embodiments, a width of source/drain structures 150 (e.g., along the y-direction) is different than a thickness of source/drain structures 150 (e.g., along the z-direction). In some embodiments, such dimension difference is provided to doped semiconductor layers 160 (e.g., widths thereof may be greater than thicknesses thereof).

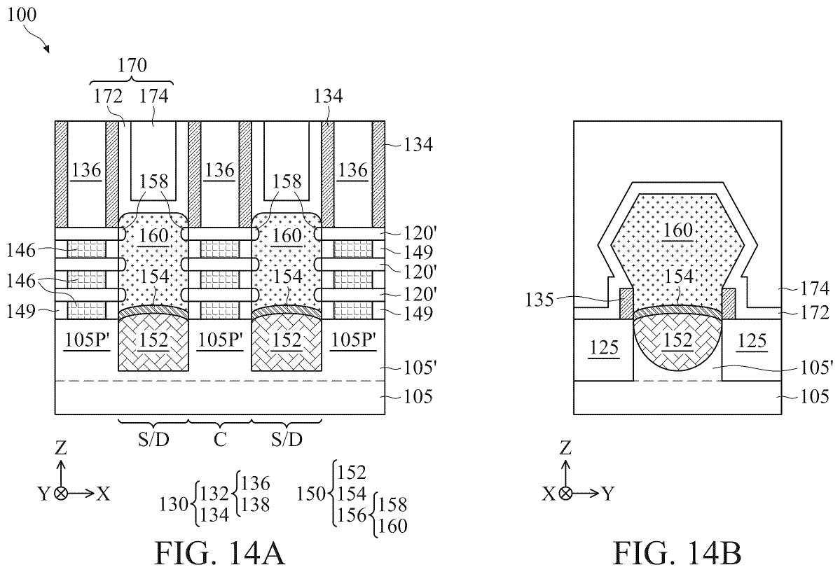

Referring to FIG. 14A and FIG. 14B, fabrication of device 100 may include forming a dielectric layer 170 over source/drain structures 150. Dielectric layer 170 may fill spaces between adjacent gate structures 130, such as spaces between gate spacers thereof, and spaces between adjacent source/drain structures 150. Forming dielectric layer 170 may include depositing a contact etch stop layer (CESL) 172, depositing an interlayer dielectric (ILD) layer 174 over CESL 172, and performing a CMP and/or other planarization process until reaching dummy gate stacks 132 (e.g., hard masks 138 thereof). In some embodiments, the planarization process may partially remove dummy gate stacks 132, such as hard masks 138 thereof, to expose underlying dummy (e.g., poly) gates 136. The planarization process may reduce heights of dummy gate stacks 132 and/or gate spacers 134, in some embodiments.

ILD layer 174 includes a dielectric material including, for example, silicon oxide, carbon doped silicon oxide, silicon nitride, silicon oxynitride, tetraethylorthosilicate (TEOS)-formed oxide, BSG, PSG, borophosphosilicate glass, fluorosilicate glass, xerogel, aerogel, amorphous fluorinated carbon, parylene, benzocyclobutene-based (BCB) dielectric material, polyimide, other suitable dielectric material, or combinations thereof. In some embodiments, ILD layer 174 includes a low-k dielectric material having a dielectric constant that is less than a dielectric constant of silicon dioxide (e.g., k<3.9). In some embodiments, ILD layer 174 includes a dielectric material having a dielectric constant that is less than about 2.5 (i.e., an extreme low-k (ELK) dielectric material), such as porous silicon dioxide, silicon carbide, carbon-doped oxide (e.g., a SiCOH-based material having, for example, Si—CH₃ bonds), or combinations thereof, each of which is tuned/configured to exhibit a dielectric constant less than about 2.5. CESL 172 includes a material different than ILD layer 174, such as a dielectric material that is different than the dielectric material of ILD layer 174. For example, where ILD layer 174 includes a silicon-and-oxygen comprising low-k dielectric material, CESL 172 may include silicon and nitrogen, such as silicon nitride or silicon oxynitride. ILD layer 174 and/or CESL 172 may have a multilayer structure and/or include multiple dielectric materials.

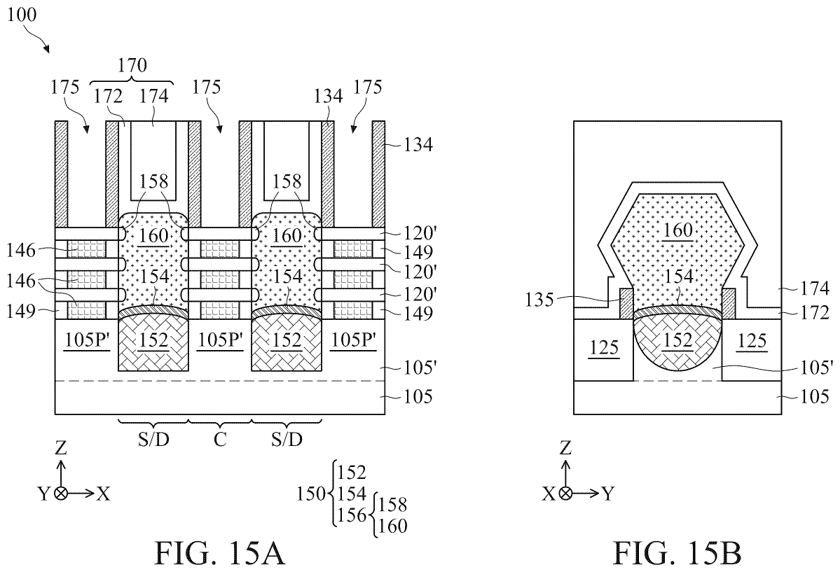

Referring to FIGS. 15A-17A and FIGS. 15B-17B, fabrication of device 100 may include a gate replacement process, which replaces dummy gate stacks 132 and sacrificial oxide layers 146 with gate stacks 180. Gate stacks 180 (also referred to as high-k/metal gates) are disposed between respective gate spacers 134, between respective inner spacers 149, between respective channel layers 120′, and between respective channel layers 120′ and respective mesas 105P′. Each gate stack 180 may include a respective gate dielectric 182 and a respective gate electrode 184. In the depicted embodiment, where device 100 includes GAA transistors, gate stacks 180 may surround and engage respective channel layers 120′, for example, in the Y-Z plane (see, e.g., FIG. 17C). In some embodiments, gate stacks 180 may wrap and/or partially surround respective channel layers 120′ (i.e., be disposed on at least two sides thereof).

Referring to FIG. 15A and FIG. 15B, dummy gate stacks 132 are removed from gate structures 130 to form gate openings 175. Gate openings 175 expose channel regions, which include channel layers 120′ and sacrificial oxide layers 146. In some embodiments, an etching process selectively removes dummy gate stacks 232 (e.g., poly gates) with negligible (to no) removal of dielectric layer 170, gate spacers 134, inner spacers 149, sacrificial oxide layers 146, semiconductor layers 120, channel layers 120′, or combinations thereof. The etching process is a dry etch, a wet etch, other suitable etch process, or combinations thereof. In some embodiments, the etching process uses a patterned mask layer as an etch mask, where the patterned mask layer covers dielectric layer 170 and/or gate spacers 134. In some embodiments, dummy gate dielectric layers (e.g., dummy oxide layers) of dummy gate stacks 132 remain.

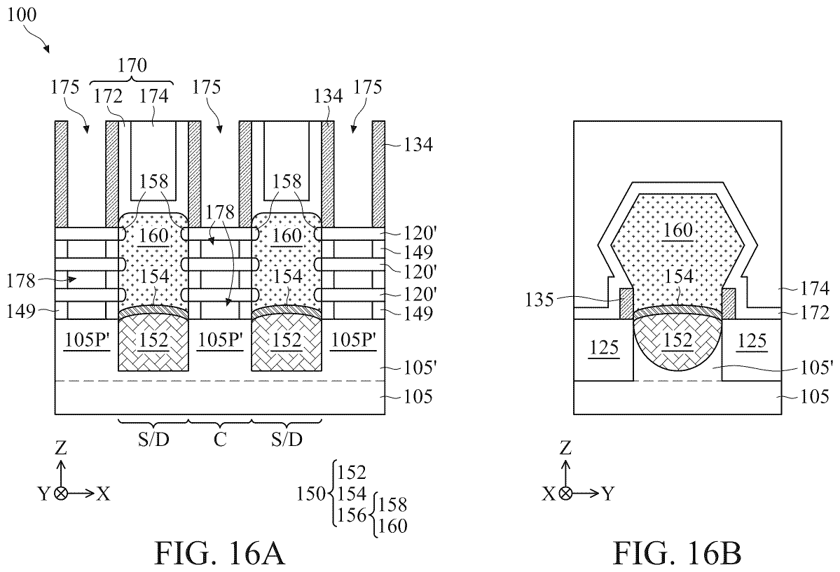

Referring to FIG. 16A and FIG. 16B, sacrificial oxide layers 146 are removed from channel regions, thereby forming gaps (openings) 178 that expose channel layers 120′. Gate openings 175 are thus extended between channel layers 120′ and between channel layers 120′ and mesas 105P′. In some embodiments, an etching process selectively removes sacrificial oxide layers 146 with respect to mesas 105P′, channel layers 120′, gate spacers 134, inner spacers 149, dielectric layer 170, or combinations thereof. In other words, the etching process removes sacrificial oxide layers 146 with negligible (to no) removal of mesas 105P′, channel layers 120′, gate spacers 134, inner spacers 149, dielectric layer 170, or combinations thereof. For example, an etchant is selected for the etching process that etches an oxide material (e.g., sacrificial oxide layers 146) at a higher rate than silicon (e.g., channel layers 120′ and mesas 105P′) and dielectric materials having compositions different than the oxide material (e.g., gate spacers 134, inner spacers 149, CESL 172, ILD layer 174, etc.) (i.e., the etchant has a high etch selectivity with respect to the oxide material). The etching process is a dry etch, a wet etch, other suitable etch, or combinations thereof. In some embodiments, the etching process removes any remainder of dummy gate stacks 232, such as dummy oxide layers thereof.

Referring to FIGS. 17A-17C, gate stacks 180 are formed in gate openings 175 and/or gaps 178. For example, gate dielectrics 182 are formed in and partially fill gate openings 175 and gaps 178. Gate dielectrics 182 are disposed on respective channel layers 120′, respective inner spacers 149, respective gate spacers 134, substrate isolation structures 125, or combinations thereof. Gate dielectrics 182 include at least one dielectric layer, such as an interfacial layer and/or a high-k dielectric layer. Interfacial layers include a dielectric material, such as SiO₂, SiGeOₓ, HfSiO, SiON, other dielectric material, or combinations thereof. Interfacial layers are formed by thermal oxidation, chemical oxidation, ALD, CVD, other process, or combinations thereof. High-k dielectric layers include a high-k dielectric material, which generally refers to a dielectric material having a dielectric constant greater than a dielectric constant of silicon dioxide, such as HfO₂, HfSiO, HfSiO₄, HfSiON, HfLaO, HfTaO, HfTiO, HfZrO, HfAlOx, ZrO, ZrO₂, ZrSiO₂, AlO, AlSiO, Al₂O₃, TiO, TiO₂, LaO, LaSiO, LaO₃, La₂O₃, Ta₂O₃, Ta₂O₅, Y₂O₃, SrTiO₃, BaZrO, BaTiO₃, (Ba,Sr)TiO₃ (BST), HfO₂—Al₂O₃, other high-k dielectric material, or combinations thereof. High-k dielectric layers are formed by ALD, CVD, PVD, an oxide-based deposition process, other process, or combinations thereof. In some embodiments, high-k dielectric layers include a hafnium-based oxide (e.g., HfO₂) layer. In some embodiments, high-k dielectric layers include a zirconium-based oxide (e.g., ZrO₂) layer.

Gate electrodes 184 are formed in and fill remainders of gate openings 175 and gaps 178. Gate electrodes 184 are disposed on gate dielectrics 182. Gate electrodes 184 include an electrically conductive layer formed of an electrically conductive material, such as Al, Cu, Ti, Ta, W, Mo, Co, TaN, NiSi, CoSi, TiN, WN, TiAl, TiAlN, TaCN, TaC, TaSiN, other electrically conductive material, or combinations thereof. In some embodiments, the electrically conductive layer includes a work function layer tuned to have a desired work function (e.g., an n-type work function or a p-type work function). The work function layer includes work function metal(s) and/or alloys thereof, such as Ti, Ta, Al, Ag, Mn, Zr, W, Ru, Mo, TiC, TiAl, TiAlC, TiAlSiC, TaC, TaCN, TaSiN, TiSiN, TiN, TaN, TaSN, WN, WCN, ZrSi₂, MoSi₂, TaSi₂, NiSi₂, TaAl, TaAlC, TaSiAlC, TiAlN, or combinations thereof. In some embodiments, the electrically conductive layer includes a bulk layer over the gate dielectric and/or the work function layer. The bulk layer may include Al, W, Cu, Ti, Ta, TiN, TaN, polysilicon, other suitable metal(s) and/or alloys thereof, or combinations thereof. In some embodiments, the electrically conductive layer includes a barrier layer over the work function layer and/or the gate dielectric. The barrier layer includes a material that may prevent diffusion and/or reaction of constituents between adjacent layers and/or promote adhesion between adjacent layers, such as between the work function layer and the bulk layer. In some embodiments, the barrier layer includes metal and nitrogen, such as titanium nitride, tantalum nitride, tungsten nitride, titanium silicon nitride, tantalum silicon nitride, other suitable metal nitride, or combinations thereof.

Forming gate stacks 180 may include depositing gate dielectric material (e.g., interfacial layers, high-k dielectric layers, etc.) that partially fill gate openings 175 and/or gaps 178, depositing gate electrode material (e.g., work function layers, barrier layers, bulk layers, etc.) over the gate dielectric material that fills remainders of gate openings 175 and/or gaps 178, and performing a planarization process (e.g., CMP) to remove portions of the gate dielectric material and/or portions of the gate electrode material over dielectric layer 170. In some embodiments, fabrication of device 100 may further include etching back gate stacks 180 and forming hard masks (e.g., self-aligned cap (SAC) structures) over the etched-back gate stacks 180. The SAC structures include a material that is different than dielectric layer 170 and/or subsequently formed dielectric layers to achieve etch selectivity. In some embodiments, the SAC structures include silicon and nitrogen and/or carbon, such as silicon nitride, silicon oxynitride, silicon carbide, silicon oxycarbide, silicon carbonitride, silicon oxycarbonitride, other silicon nitride, other silicon carbide, or combinations thereof. In some embodiments, the SAC structures include metal and oxygen and/or nitrogen, such as aluminum oxide, aluminum nitride, aluminum oxynitride, zirconium oxide, zirconium nitride, hafnium oxide, zirconium aluminum oxide, other metal oxide, other metal nitride, or combinations thereof.

Device 100 may thus include at least one transistor T. Transistor T may include respective channels (e.g., channel layers 120′), source/drains (e.g., source/drain structures 150), and a respective gate (e.g., gate stack 180). Gate stack 180 is disposed between respective source/drains (e.g., source/drain structures 150) along the x-direction, and inner spacers 149 are disposed between gate stack 180 and respective source/drains. Further, gate stack 180 engages respective channels (e.g., channel layers 120′), and the respective channels extend between the respective source/drains (e.g., source/drain structures 150) along the x-direction. In the depicted embodiment, transistor T is a GAA transistor. Gate stack 180 may thus surround its respective channel layers, and along the gate lengthwise direction, gate stack 180 may include a gate dielectric (e.g., gate dielectric 182) and a gate electrode (e.g., gate electrode 184) that surrounds its respective channels. In some embodiments, gate stack 180 may wrap and/or partially surround its respective channel layers (i.e., disposed on at least two sides thereof), such as where the transistor T is a fork-sheet transistor or other type of multigate transistor.

In the depicted embodiment, transistor T is a p-type transistor. For example, transistor T may include silicon channels (e.g., channel layers 120′ may be silicon layers) and silicon germanium epitaxial source/drains (e.g., doped semiconductor layers 156 may be silicon germanium structures). Because transistor T is fabricated using disposable/dummy oxide interposers (e.g., sacrificial oxide layers 146), source/drain structures 150 exhibit improved stress characteristics and/or transistor T exhibits improved performance. For example, because sacrificial semiconductor layers 115 are replaced with sacrificial oxide layers 146 before source/drain fabrication, constituents from dummy interposers (e.g., sacrificial semiconductor layers 115) will not migrate into channel layers 120′ during fabrication of source/drain structures 150, such as migration of germanium that may occur during thermal processes associated with such fabrication. Reducing and/or preventing migration of constituents (e.g., germanium) from the dummy interposers hinders undesired changes in stress characteristics of channel layers 120′, such as the undesired introduction of tensile stress into compressively stressed channel layers 120′, that may negatively impact performance of p-type transistors. P-type transistors, such as transistor T, fabricated according to the disclosed methods (e.g., which implement sacrificial oxide layers 146) thus exhibit improved performance, such as less channel resistance and/or improved stress characteristics (e.g., minimal to no tensile stress). In some instances, p-type transistors fabricated as described herein (i.e., using dummy oxide interposers) exhibit less leakage current, less parasitic capacitance, less channel resistance, less bottom source/drain insulation RO penalty, or combinations thereof than p-type transistors having bottom source/drain insulation fabricated using dummy semiconductor (e.g., SiGe) interposers.

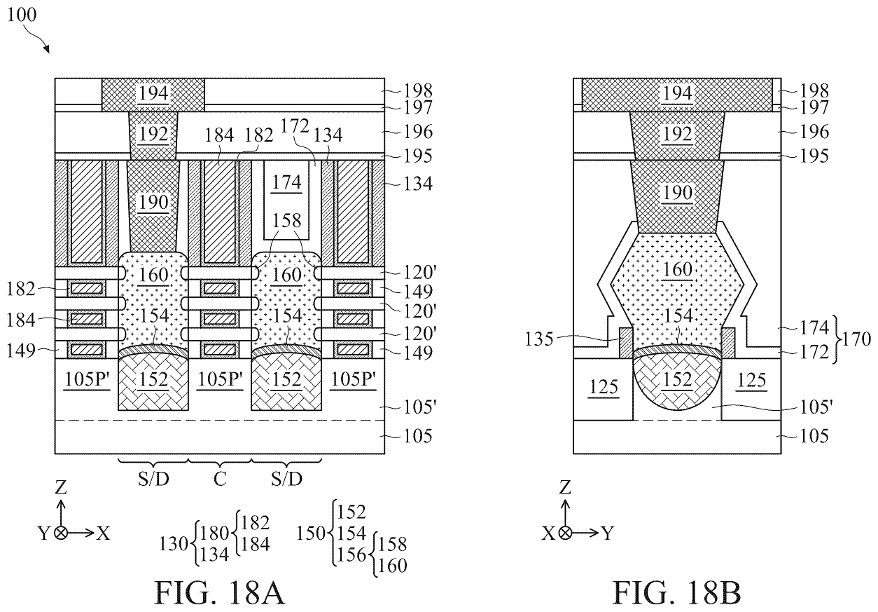

Referring to FIG. 18A and FIG. 18B, fabrication of device 100 may include forming one or more frontside, upper source/drain contacts, such as a source/drain contact 190. In some embodiments, forming source/drain contact 190 includes forming a source/drain contact opening in dielectric layer 170 that exposes a respective source/drain structure 150, depositing at least one electrically conductive material (e.g., a metal bulk material) over dielectric layer 170 that fills the source/drain contact opening, and performing a planarization process to remove any of the electrically conductive material that is disposed over a top of dielectric layer 170 and/or tops of gate structures 130. The planarization process may be performed until reaching and exposing gate stacks 180 (or, in some embodiments, SAC structures overlying etched-back gate stacks 180). Remainders of the electrically conductive material form metal plugs and, in some embodiments, one or more liners of source/drain contact 190. The electrically conductive material includes tungsten, ruthenium, cobalt, molybdenum, copper, aluminum, titanium, tantalum, iridium, palladium, platinum, nickel, tin, gold, silver, other suitable metal, alloys thereof, or combinations thereof. In some embodiments, a silicide layer is formed over doped semiconductor layer 160 before depositing the electrically conductive material. In some embodiments, an electrical conductivity of the silicide layer (which may be referred to as a frontside (or top) silicide layer) is greater than an electrical conductivity of doped semiconductor layer 160 and less than an electrical conductivity of source/drain contact 200.

Fabrication of device 100 may further include frontside back end-of-line (BEOL) processing to form metallization layers of a frontside multilayer interconnect (F-MLI) structure. The F-MLI structure may electrically connect devices (e.g., transistors (e.g., transistor T), resistors, capacitors, inductors, etc.), components of devices (e.g., gates and/or source/drains), devices within the F-MLI structure, components of the F-MLI structure, or combinations thereof, such that the devices and/or components thereof can operate as specified by design requirements. The metallization layers may route signals between the devices and/or the components thereof and/or distribute signals (e.g., clock signals, voltage signals, ground signals, other signals, or combinations thereof) to the devices and/or the components thereof. In some embodiments, a metallization layer/level includes at least one interconnect structure disposed in an insulation layer, such as a via (e.g., a source/drain via 192) and an electrically conductive line (e.g., a metal line 194) disposed in a dielectric layer (e.g., a CESL 195, an ILD layer 196, a CESL 197, and an ILD layer 198), where the via (e.g., source/drain via 192) connects the electrically conductive line (e.g., metal line 194) to an underlying device-level interconnect (e.g., source/drain contact 190) or a metal line of an interconnect in a different metallization layer.

In some embodiments, forming source/drain via 192 includes forming a dielectric layer (e.g., CESL 195 and ILD layer 195, which may be configured and formed similar to CESL 172 and ILD layer 174, respectively) over dielectric layer 170, forming a source/drain via opening in the dielectric layer that exposes source/drain contact 190, depositing at least one electrically conductive material (e.g., a metal bulk material) over the dielectric layer that fills the source/drain via opening, and performing a planarization process to remove any of the electrically conductive material disposed over a top of the dielectric layer. The planarization process may be performed until reaching and exposing ILD layer 196. Remainders of the electrically conductive material form metal plugs and, in some embodiments, one or more liners of source/drain via 192. In some embodiments, forming metal liner 194 includes forming a dielectric layer (e.g., CESL 197 and ILD layer 198, which may be configured and formed similar to CESL 195 and ILD layer 196, respectively) over ILD layer 196, patterning the dielectric layer to forming openings therein (such as an opening therein that exposes source/drain via 192), depositing at least one electrically conductive material (e.g., a metal bulk material) over the dielectric layer that fills the openings, and performing a planarization process to remove any of the electrically conductive material disposed over a top of the dielectric layer. The planarization process may be performed until reaching and exposing ILD layer 198. Remainders of the electrically conductive material form metal plugs and, in some embodiments, one or more liners of metal line 194. The electrically conductive material of source/drain via 192 and/or metal line 194 includes tungsten, ruthenium, cobalt, molybdenum, copper, aluminum, titanium, tantalum, iridium, palladium, platinum, nickel, tin, gold, silver, other suitable metal, alloys thereof, or combinations thereof. In some embodiments, source/drain via 192 and metal line 194 are formed by a dual damascene process. In such embodiments, CESL 197 and ILD layer 198 may be formed over ILD layer 196 before forming the source/drain via opening, the metal line opening may expose the source/drain via opening, and electrically conductive material for both source/drain via 192 and metal line 194 may be deposited at the same time.

Metal lines (e.g., metal line 194) of the first metallization layer can collectively be referred to as a metal one (M1) layer and individually referred to as M1 metal lines. Vias of the first metallization layer (e.g., source/drain via 192) may physically and/or electrically connect local, device-level contacts (e.g., source/drain contact 190) to metal lines (e.g., metal line 194). In such embodiments, the vias of the first metallization layer can collectively be referred to as a via zero (V0) layer (and individually referred to as V0 vias). In such embodiments, the V0 layer may be a bottommost via layer of the F-MLI structure. Additional metallization layers (levels) of the F-MLI structure may be formed over the first metallization layer. For example, BEOL processing may include forming a second metallization layer (i.e., a metal two (M2) layer and a via one (V1) layer), a third metallization layer (i.e., a metal three (M3) layer and a via two (V2) layer), a fourth metallization layer (i.e., a metal four (M4) layer and a via three (V3) layer), a fifth metallization layer (i.e., a metal five (M5) layer and a via four (V4) layer), a sixth metallization layer (i.e., a metal six (M6) layer and a via five (V5) layer), a seventh metallization layer (i.e., a metal seven (M7) layer and a via six (V6) layer) to an X metallization layer (i.e., a metal X (MX) layer and a via Y (VY) layer, where X is a total number of patterned metal line layers of the MLI feature and Y is a total number of patterned via layers of the MLI feature) over the first metallization layer. Each of the metallization layers may include a patterned metal line layer and a patterned via layer configured to provide at least one BEOL interconnect structure disposed in an insulation layer. The F-MLI structure may have any number of metal layers, via layers, dielectric layers, or combinations thereof depending on design requirements. In some embodiments, the metal layers, via layers, dielectric layers, or combinations thereof may be configured with various dimensions depending on design requirements. For example, in some embodiments, a thickness of ILD layer 196 (which may be a bottommost ILD layer of the F-MLI structure and/or of a first metallization layer thereof) is greater than a thickness of ILD layer 198 (and/or other ILD layers in metallization layers above ILD layer 196).

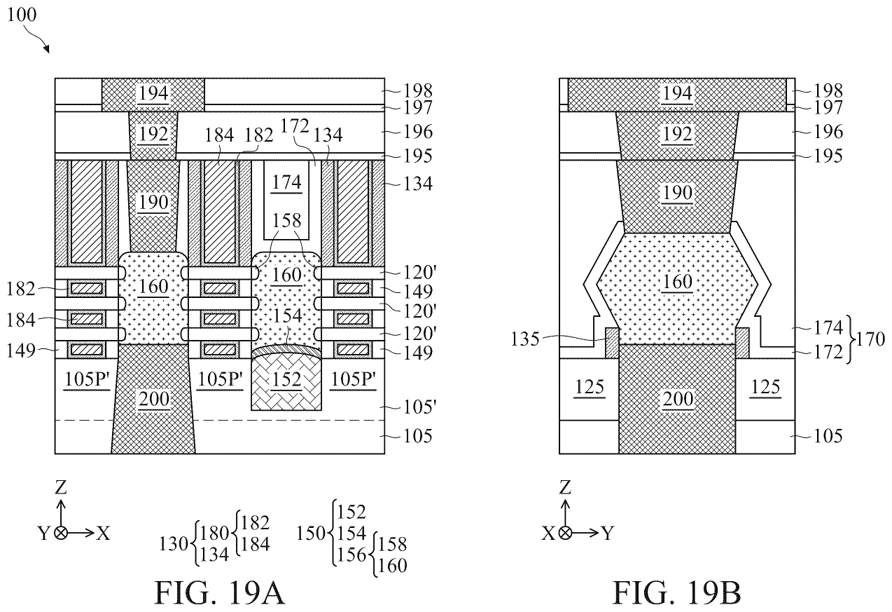

Referring to FIG. 19A and FIG. 19B, fabrication of device 100 may include forming one or more backside, lower source/drain contacts, such as a source/drain contact 200. In some embodiments, forming source/drain contact 200 includes forming a source/drain contact opening that exposes a respective doped semiconductor layer 156 of a respective source/drain structure 150 (i.e., undoped semiconductor layer 152 and insulator layer 154 are removed when forming the source/drain contact opening), depositing at least one electrically conductive material (e.g., a metal bulk material) over a backside of device 100 that fills the source/drain contact opening, and performing a planarization process to remove any of the electrically conductive material that is disposed over a backside of device 100 (which may be formed by substrate 105 or a dielectric structure that replaces a portion of substrate 105 before forming the source/drain contact opening). Remainders of the electrically conductive material form metal plugs and, in some embodiments, one or more liners of source/drain contact 200. The electrically conductive material includes tungsten, ruthenium, cobalt, molybdenum, copper, aluminum, titanium, tantalum, iridium, palladium, platinum, nickel, tin, gold, silver, other suitable metal, alloys thereof, or combinations thereof. In some embodiments, a silicide layer is formed over doped semiconductor layer 160 before depositing the electrically conductive material. In some embodiments, an electrical conductivity of the silicide layer (which may be referred to as a backside (or bottom) silicide layer) is greater than an electrical conductivity of doped semiconductor layer 160 and less than an electrical conductivity of source/drain contact 200. In some embodiments, insulator layer 154 of the respective source/drain structure 150 functions as an etch stop layer when forming the source/drain contact opening. In some embodiments, source/drain contact 200 extends through undoped semiconductor layer 152 and insulator layer 154 of the respective source/drain structure 150. In some embodiments, since the source/drain contact opening may be formed by removing undoped semiconductor layer 152 and/or insulator layer 154, source/drain contact 200 is self-aligned with source/drain structure 150 (e.g., doped semiconductor layer 160 thereof). In other words, a separate patterning process may not be needed to define the source/drain contact opening. In some embodiments, forming source/drain contact 200 includes flipping over device 100 to facilitate backside processing. In some embodiments, at least a portion of substrate 105 is replaced with a dielectric structure, such that source/drain contact 200 is disposed in and/or extends through the dielectric structure. In some embodiments, forming source/drain contact 200 includes thinning substrate 105 (e.g., reducing a thickness of substrate 105 and expose backsides of source/drain structures 150).

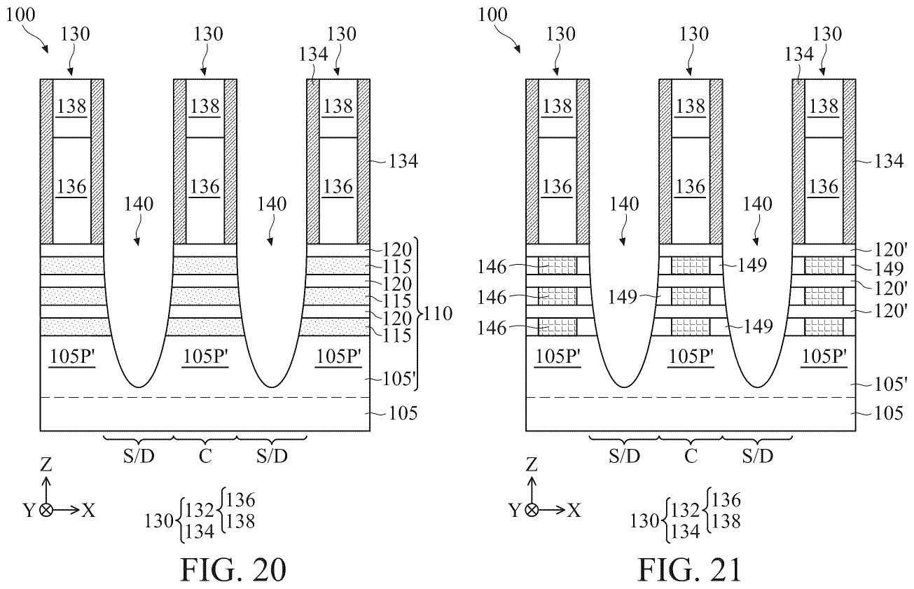

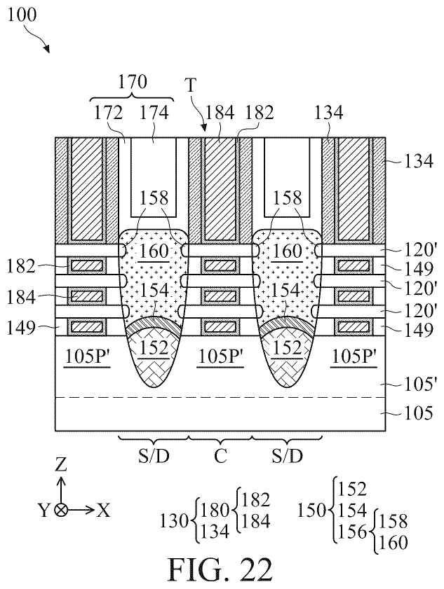

The present disclosure contemplates various variations of device 100 that may result when fabricated as described herein. In some embodiments, referring to FIGS. 20-22, source/drain recesses 140 may have sloped sidewalls, which may provide channel layers 120′, inner spacers 149, gate stacks 180, or combinations thereof with varying dimensions. In FIG. 20, source/drain recesses 140 are formed as described above with reference to FIG. 5A and FIG. 5B, except source/drain recesses 140 have sloped sidewalls in FIG. 20, instead of substantially straight sidewalls. As a result, source/drain recesses 140 have tapered widths (e.g., that decrease from top to bottom), and semiconductor layers 120 and sacrificial semiconductor layers 115 remaining in the channel regions have lengths (e.g., along the x-direction) that increase from gate structures 130 to mesas 105P′. For example, topmost semiconductor layers 120 have lengths that are less than lengths of middle semiconductor layers 120, which are less than lengths of bottommost semiconductor layers 120 (i.e., length of semiconductor layers 120 increases from top to bottom of multilayer stack). Further, topmost sacrificial semiconductor layers 115 have lengths that are less than lengths of middle sacrificial semiconductor layers 115, which are less than lengths of bottommost sacrificial semiconductor layers 115. Differences in the lengths of sacrificial semiconductor layers 115 may result in inner spacers 149 having different widths (e.g., along the x-direction) and/or sacrificial oxide layers 146 having different lengths, such as depicted in FIG. 21, which corresponds with the fabrication stage described with reference to FIG. 10A and FIG. 10B. In FIG. 21, widths of topmost inner spacers 149 are less than widths of middle inner spacers 149, which are less than widths of bottommost inner spacers 149 (i.e., widths of inner spacers 149 increase from top to bottom). In some embodiments, widths of topmost inner spacers 149 are about 3.5 nm to about 4 nm, and widths of bottommost inner spacers 149 are about 4 nm to about 4.5 nm. Further, lengths of topmost sacrificial oxide layers 146 are less than lengths of middle sacrificial oxide layers 146, which are less than lengths of bottommost sacrificial oxide layers 146 (i.e., widths of sacrificial oxide layers 146 increase from top to bottom). Differences in the lengths of sacrificial oxide layers 146 may result in portions of gate stacks 180 between inner spacers 149 having different widths (e.g., along the x-direction), such as depicted in FIG. 22, which corresponds with the fabrication stage described with reference to FIGS. 17A-17C. For example, widths of gate stack portions between topmost inner spacers 149 are less than widths of gate stack portions between middle inner spacers 149, which are less than widths of gate stack portions between bottommost inner spacers 149. FIGS. 20-22 are discussed concurrently herein for ease of description and understanding. FIGS. 20-22 have been simplified for the sake of clarity to better understand the inventive concepts of the present disclosure. Additional features may be added in device 100, and some of the features described below may be replaced, modified, or eliminated in other embodiments of device 100.

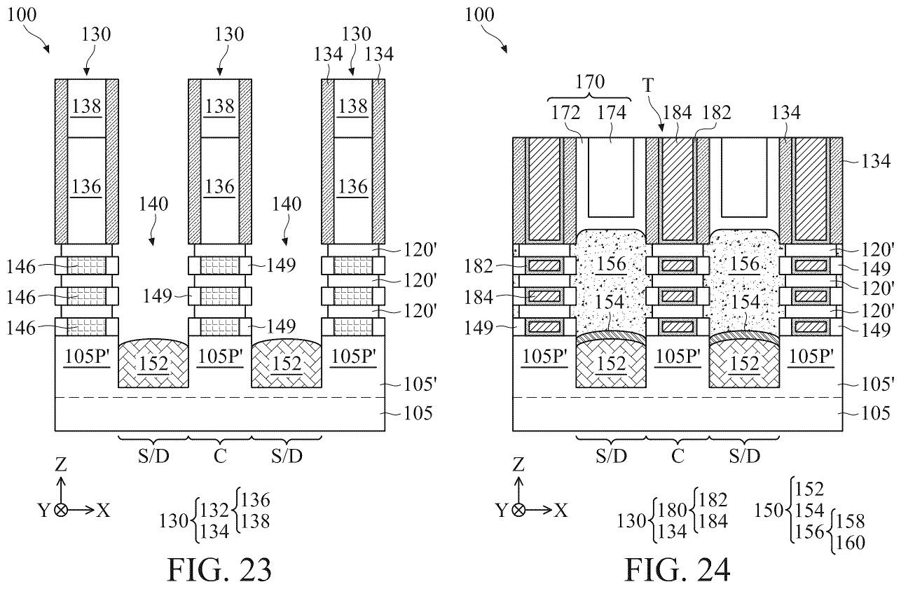

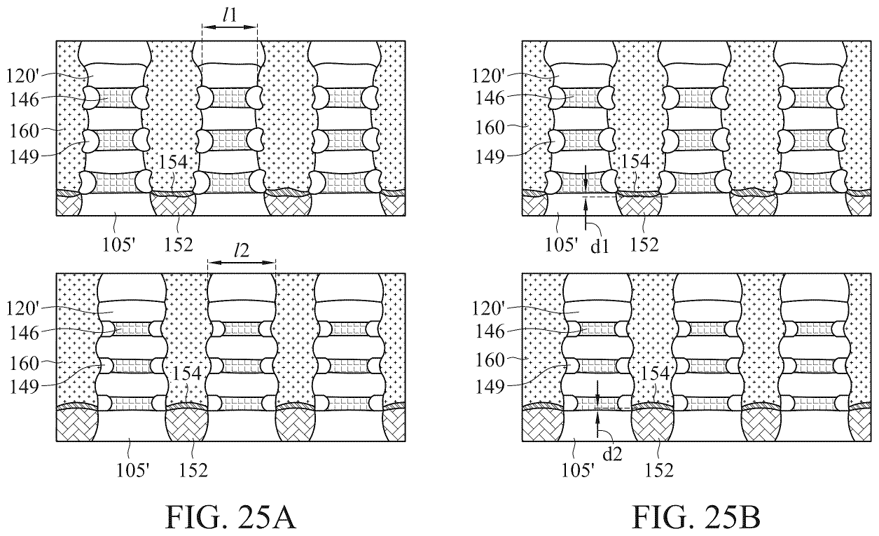

In some embodiments, referring to FIG. 23, FIG. 24, FIG. 25A, and FIG. 25B, after forming undoped semiconductor layers 152 and before forming doped semiconductor layers 156 (and insulator layers 154, in some embodiments), fabrication of device 100 may include performing an etching process (e.g., an anisotropic etch) to laterally recess channel layers 120′. For example, the etching process may laterally etch (e.g., along the x-direction) channel layers 120′ to reduce their lengths along the x-direction (FIG. 23), thereby reducing a distance between subsequently formed gate stacks 180 and doped semiconductor layers 156 (FIG. 24), which may improve performance of transistor T. In such example, lengths of channel layers 120′ are greater than lengths of sacrificial oxide layers 146 and/or greater than a width of dummy gate stacks 132, but less than a sum of a length of a given sacrificial oxide layers 146 and a total width of inner spacers 149 between which the given sacrificial oxide layer 146 is disposed, such that inner spacers 149 extend beyond channel layers 120′, such as depicted in FIG. 23. In some embodiments, the etching process may recess and/or thin undoped semiconductor layers 152. In such embodiments, tops of undoped semiconductor layers 152 may be below tops of mesas 105P′ and/or thicknesses of undoped semiconductor layers 152 may be less than undoped semiconductor layers 152 in other devices/circuit regions. In such embodiments, bottoms of insulator layers 154 may be lower than bottoms of insulator layers 154 in other devices/circuit regions. In some embodiments, device 100 may include transistors having laterally recessed channel layers 120′ (e.g., p-type transistors that form a portion of a logic region/circuit), such as depicted in FIG. 24, FIG. 25A (top devices), FIG. 25B (top devices), or combinations thereof, and transistors having channel layers 120′ that are not recessed (e.g., p-type transistors that form a portion of a memory region/circuit or n-type transistors that form a portion of a logic region or a memory region), such as depicted in FIG. 17A, FIG. 25A (bottom devices), FIG. 25B (bottom devices), or combinations thereof. In some embodiments, a length 11 of laterally recessed channel layers 120′ (e.g., FIG. 24 and/or top devices of FIG. 25A) may be about 20 nm to about 22 nm, and a length 12 of channel layers 120′ (e.g., FIG. 17A and/or top devices of FIG. 25A) that have not been laterally recessed may be about 25 nm to about 27 nm. In some embodiments, in the transistors having laterally recessed channel layers 120′ (e.g., FIG. 24 and/or top devices of FIG. 25B), tops of undoped semiconductor layers 152 are about 4 nm to about 5 nm below tops of mesas 105P′ (e.g., a distance d1), while in the transistors having channel layers 120′ that are not recessed (e.g., FIG. 17A and/or bottom devices of FIG. 25B), tops of undoped semiconductor layers 152 are about 0 nm to about 2 nm above tops of mesas 105P′ (e.g., a distance d2). In some embodiments, thicknesses of undoped semiconductor layers 152 of the transistors having laterally recessed channel layers 120′ (e.g., FIG. 24 and/or top devices of FIG. 25A) may be less than thicknesses of undoped semiconductor layers 152 of the transistors having channel layers 120′ that are not recessed (e.g., FIG. 17A and/or bottom devices of FIG. 25B). In some embodiments, transistor T is a p-type transistor, and device 100 further includes an n-type transistor (which may form a portion of a logic region/circuit or a memory region/circuit), and a length of channel layers of the n-type transistor may be about 25 nm to about 27 nm (e.g., bottom devices of FIG. 25A and/or FIG. 25B), and tops of undoped semiconductor layers of source/drain structure of the n-type transistor may be about 0 nm to about 2 nm above tops of mesas thereof e.g., bottom devices of FIG. 25A and/or FIG. 25B). FIG. 23, FIG. 24, FIG. 25A, and FIG. 25B are discussed concurrently herein for ease of description and understanding. FIG. 23, FIG. 24, FIG. 25A, and FIG. 25B have been simplified for the sake of clarity to better understand the inventive concepts of the present disclosure. Additional features may be added, and some of the features described below may be replaced, modified, or eliminated.

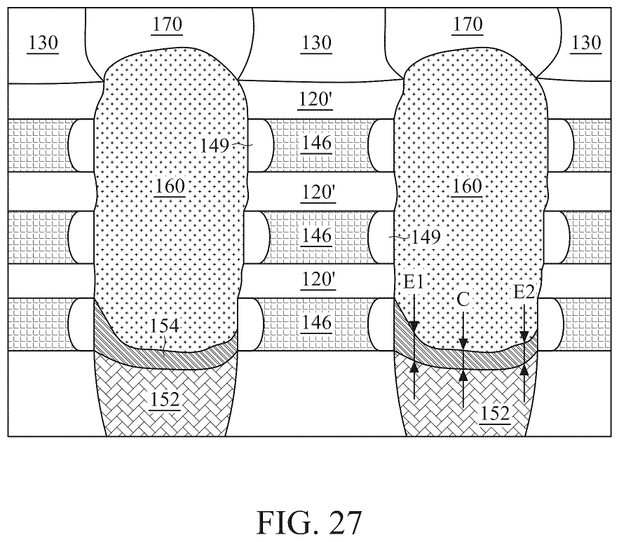

Bottom source/drain insulation (e.g., insulator layers 154) may have various profiles and/or dimensions as a result of variations during processing. In some embodiments, referring to FIG. 12A and FIG. 12B, insulator layers 154 have convex top surfaces. In some embodiments, referring to FIG. 27, insulator layers 154 have concave top surfaces. In some embodiments, insulator layers 154 have substantially uniform thicknesses (e.g., along the z-direction). For example, a thickness of a center portion of insulator layers 154 may be substantially the same as thicknesses of edge portions (also referred to as corner portions) of insulator layers 154. In some embodiments, the thickness is about 3 nm to about 5 nm. In some embodiments, insulator layers 154 have thickness variations. For example, referring to FIG. 27, insulator layers 154 may have a left edge/corner having a thickness E1, a right edge/corner having a thickness E2, and a center having a thickness C, and thickness E1, thickness E2, and thickness C may be different. In some embodiments, thickness E1 is about 3 nm to about 5 nm, thickness E2 is about 3 nm to about 5 nm, and thickness C is about 3 nm to about 5 nm. In some embodiments, thickness C is greater than thickness E1 and thickness E2. In some embodiments, thickness C is less than thickness E1 and thickness E2. In some embodiments, thickness C is greater than thickness E2 and less than thickness E1. In some embodiments, thickness C is less than thickness E2 and greater than thickness E1. In some embodiments, thickness E1 is greater than thickness E2. In some embodiments, thickness E2 is greater than thickness E1. In some embodiments, thickness of insulator layers 154 decreases from left to right (i.e., thickness E1 is greater than thickness C, and thickness C is greater than thickness E2). In some embodiments, thickness variations of insulator layers 154 depend on dimensions of channel layers 120′ (e.g., widths and/or lengths thereof). For example, thicknesses of insulator layers 154 may decrease as channel width increases. In some embodiments, thicknesses of insulator layers 154 of a first device having a first channel width (e.g., center thicknesses of about 4 nm to about 5 nm and corner thicknesses of about 3 nm to about 6 nm) may be greater than thicknesses of insulator layers 154 of a second device having a second width greater than the first width (e.g., center thicknesses of about 4 nm to about 4.5 nm and corner thicknesses of about 2.5 nm to about 4.5 nm), which may be greater than thicknesses of insulator layers 154 of a third device having a third width greater than the second width (e.g., center thicknesses of about 3 nm to about 4 nm and corner thicknesses of about 2 nm to about 3.5 nm). In another example, thickness variations of insulator layers 154 (e.g., differences between center thickness and edge/corner thicknesses thereof) may decrease as channel width increases. In some embodiments, thickness variations of insulator layers 154 depend on contacted poly pitch (CPP) (i.e., a distance between adjacent gates (e.g., gate structures 130)). For example, thickness variations of insulator layers 154 (e.g., differences between center thickness and corner thicknesses thereof) may increase as CPP increases. In some embodiments, a thickness of channel layers 120′ (e.g., along the z-direction) is about 5 nm to about 6 nm. In some embodiments, a thickness of sacrificial oxide layers 146 (e.g., along the z-direction) is greater than channel layers 120′. For example, in the depicted embodiment, a thickness of sacrificial oxide layers 146 is greater than channel layers 120′. In some embodiments, a thickness of sacrificial oxide layers 146 is about 6 nm to about 7 nm.

The present disclosure provides for many different embodiments. Methods of fabricating multigate transistors using dummy oxide interposers are disclosed herein. An exemplary method includes forming a multilayer stack that includes first semiconductor layers, first sacrificial layers having a first composition, and a protrusion. The first semiconductor layers and the first sacrificial layers are disposed over the protrusion. A source/drain recess is formed by removing the first semiconductor layers, the first sacrificial layers, and a portion of the protrusion in a source/drain region, and a source/drain structure is formed in the source/drain recess. The source/drain structure includes a second semiconductor layer and an insulator layer, and the insulator layer is disposed between the second semiconductor layer and the protrusion. Before forming the source/drain structure, the first sacrificial layers are replaced with second sacrificial layers having a second composition different than the first composition. After forming the source/drain structure, the second sacrificial layers are removed from a channel region to form a portion of a gate opening. A gate stack is formed in the portion of the gate opening.

In some embodiments, the method further includes replacing ends of the second sacrificial layers with inner spacers before forming the source/drain structure. In some embodiments, the method further includes forming a frontside source/drain contact to the source/drain structure. In some embodiments, the method further includes forming a backside source/drain contact to the source/drain structure.

In some embodiments, the first semiconductor layers are formed of a first semiconductor material, the first sacrificial layers are formed of a second semiconductor material, and the second sacrificial layers are formed of a dielectric material. In some embodiments, the first semiconductor material is silicon, the second semiconductor material is silicon germanium, and the dielectric material is silicon oxide. In some embodiments, the insulator layer is a silicon nitride layer.

In some embodiments, the source/drain structure further includes a third semiconductor layer disposed between the insulator layer and the protrusion. The second semiconductor layer is doped, and the third semiconductor layer is undoped. In some embodiments, the method further includes laterally recessing the first semiconductor layers after forming the third semiconductor layer and before forming the insulator layer and the second semiconductor layer. In some embodiments, laterally recessing the first semiconductor layers reduces a thickness of the third semiconductor layer.

Another exemplary method includes forming a multilayer stack that includes semiconductor layers, sacrificial semiconductor layers, and a substrate extension. The method further includes forming a source/drain recess by removing the semiconductor layers, the sacrificial semiconductor layers, and a portion of the substrate extension in a source/drain region and forming a source/drain structure in the source/drain recess. The source/drain structure may be formed by forming an undoped semiconductor layer over the substrate extension that partially fills the source/drain recess, forming an insulator layer over the undoped semiconductor layer that partially fills the source/drain recess, and forming a doped semiconductor layer over the insulator layer that fills a remainder of the source/drain recess. The method further includes, before forming the source/drain structure in the source/drain recess, replacing the sacrificial semiconductor layers in a channel region with sacrificial oxide layers. The method further includes, after forming the source/drain structure in the source/drain recess, replacing the sacrificial oxide layers in the channel region with a gate stack.

In some embodiments, the method further includes laterally recessing the sacrificial oxide layers to form inner spacer notches before forming the source/drain structure in the source/drain recess and forming inner spacers in the inner spacer notches. In some embodiments, the method further includes forming a gate structure over the multilayer stack in the channel region before forming the source/drain recess. The gate structure may include a dummy gate and gate spacers. In such embodiments, the method further includes removing the dummy gate to form a gate opening after forming the source/drain structure and before replacing the sacrificial oxide layers with a gate stack. The gate stack fills the gate opening.

In some embodiments, forming the insulator layer includes forming a nitrogen-comprising dielectric layer over the undoped semiconductor layer. In some embodiments, the method further includes laterally recessing the semiconductor layers in the channel region after forming the undoped semiconductor layer and before forming the insulator layer. In some embodiments, the method further includes forming a frontside source/drain contact to the source/drain structure. In some embodiments, the method further includes forming a backside source/drain contact to the source/drain structure. In some embodiments, forming the backside source/drain contact includes removing the undoped semiconductor layer and the insulator layer. In some embodiments, the source/drain recess has sloped sidewalls.

Another exemplary method includes forming a multilayer stack that includes first semiconductor layers, sacrificial semiconductor layers, and a substrate extension. A source/drain recess is formed by removing the first semiconductor layers, sacrificial semiconductor layers, and a portion of the substrate extension in a source/drain region, and a source/drain structure is formed in the source/drain recess. The source/drain structure includes a second semiconductor layer and an insulator layer, and the insulator layer is disposed between the second semiconductor layer and the substrate extension. Before forming the source/drain structure, the sacrificial semiconductor layers are replaced with sacrificial dielectric layers. After forming the source/drain structure, the sacrificial dielectric layers are removed from a channel region to form a portion of a gate opening. A gate stack is formed in the portion of the gate opening.

An exemplary device structure includes a first p-type transistor that includes a first semiconductor layer having a first length that extends from a first p-doped source/drain to a second p-doped source/drain, a first gate stack disposed over the first semiconductor layer, and first inner spacers. The device structure further includes a second p-type transistor that includes a second semiconductor layer having a second length that extends from a third p-doped source/drain to a fourth p-doped source/drain, a second gate stack disposed over the second semiconductor layer, and second inner spacers. A portion of the first gate stack is disposed between the first inner spacers, the first inner spacers extend beyond ends of the first semiconductor layer, and the first p-doped source/drain is disposed on a first source/drain insulation layer. A portion of the second gate stack is disposed between the second inner spacers, the second length is greater than the first length, and the third p-doped source/drain is disposed on a second source/drain insulation layer.

In some embodiments, the first p-type transistor forms a portion of logic circuit, and the second p-type transistor forms a portion of a memory circuit. In some embodiments, the first gate stack is disposed over a first semiconductor mesa, the second gate stack is disposed over a second semiconductor mesa, and a top of the first source/drain insulation layer is disposed below a top of the first semiconductor mesa and a top of the second source/drain insulation layer is disposed above a top of the second semiconductor mesa.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a multilayer stack that includes first semiconductor layers and first sacrificial layers having a first composition, wherein the multilayer stack is disposed over a protrusion;
forming a source/drain recess by removing the first semiconductor layers, the first sacrificial layers, and a portion of the protrusion in a source/drain region;
forming a source/drain structure in the source/drain recess, wherein the source/drain structure includes a second semiconductor layer and an insulator layer, wherein the insulator layer is disposed between the second semiconductor layer and the protrusion;
before forming the source/drain structure, replacing the first sacrificial layers with second sacrificial layers having a second composition different than the first composition;
after forming the source/drain structure, removing the second sacrificial layers from a channel region to form a portion of a gate opening; and
forming a gate stack in the portion of the gate opening.

2. The method of claim 1, wherein the first semiconductor layers are formed of a first semiconductor material, the first sacrificial layers are formed of a second semiconductor material, and the second sacrificial layers are formed of a dielectric material.

3. The method of claim 2, wherein the first semiconductor material is silicon, the second semiconductor material is silicon germanium, and the dielectric material is silicon oxide.

4. The method of claim 3, wherein the insulator layer is a silicon nitride layer.

5. The method of claim 1, further comprising replacing ends of the second sacrificial layers with inner spacers before forming the source/drain structure.

6. The method of claim 1, wherein the source/drain structure further includes a third semiconductor layer disposed between the insulator layer and the protrusion, wherein the second semiconductor layer is doped and the third semiconductor layer is undoped.

7. The method of claim 6, further comprising laterally recessing the first semiconductor layers after forming the third semiconductor layer and before forming the insulator layer and the second semiconductor layer.

8. The method of claim 7, wherein the laterally recessing the first semiconductor layers reduces a thickness of the third semiconductor layer.

9. The method of claim 1, further comprising:
forming a frontside source/drain contact to the source/drain structure; and
forming a backside source/drain contact to the source/drain structure.

10. A method comprising:
forming a multilayer stack that includes semiconductor layers, sacrificial semiconductor layers, and a substrate extension;
forming a source/drain recess by removing the semiconductor layers, the sacrificial semiconductor layers, and a portion of the substrate extension in a source/drain region;
forming a source/drain structure in the source/drain recess by:
forming an undoped semiconductor layer over the substrate extension that partially fills the source/drain recess,
forming an insulator layer over the undoped semiconductor layer that partially fills the source/drain recess, and
forming a doped semiconductor layer over the insulator layer that fills a remainder of the source/drain recess;
before forming the source/drain structure in the source/drain recess, replacing the sacrificial semiconductor layers in a channel region with sacrificial oxide layers; and
after forming the source/drain structure in the source/drain recess, replacing the sacrificial oxide layers in the channel region with a gate stack.

11. The method of claim 10, further comprising:
laterally recessing the sacrificial oxide layers to form inner spacer notches before forming the source/drain structure in the source/drain recess; and
forming inner spacers in the inner spacer notches.

12. The method of claim 10, further comprising:
forming a gate structure over the multilayer stack in the channel region before forming the source/drain recess, wherein the gate structure includes a dummy gate and gate spacers;
removing the dummy gate to form a gate opening after forming the source/drain structure and before replacing the sacrificial oxide layers with a gate stack; and
wherein the gate stack fills the gate opening.

13. The method of claim 10, wherein the forming the insulator layer includes forming a nitrogen-comprising dielectric layer over the undoped semiconductor layer.

14. The method of claim 10, further comprising laterally recessing the semiconductor layers in the channel region after forming the undoped semiconductor layer and before forming the insulator layer.

15. The method of claim 10, further comprising forming a backside source/drain contact to the source/drain structure.

16. The method of claim 15, wherein the forming the backside source/drain contact includes removing the undoped semiconductor layer and the insulator layer.

17. The method of claim 10, wherein the source/drain recess has sloped sidewalls.

18. A device structure comprising:
a first p-type transistor that includes a first semiconductor layer having a first length that extends from a first p-doped source/drain to a second p-doped source/drain, a first gate stack disposed over the first semiconductor layer, and first inner spacers, wherein a portion of the first gate stack is disposed between the first inner spacers, the first inner spacers extend beyond ends of the first semiconductor layer, and the first p-doped source/drain is disposed on a first source/drain insulation layer; and
a second p-type transistor that includes a second semiconductor layer having a second length that extends from a third p-doped source/drain to a fourth p-doped source/drain, a second gate stack disposed over the second semiconductor layer, and second inner spacers, wherein a portion of the second gate stack is disposed between the second inner spacers, the second length is greater than the first length, and the third p-doped source/drain is disposed on a second source/drain insulation layer.

19. The device structure of claim 18, wherein the first p-type transistor forms a portion of logic circuit, and the second p-type transistor forms a portion of a memory circuit.

20. The device structure of claim 18, wherein:
the first gate stack is disposed over a first semiconductor base portion;
the second gate stack is disposed over a second semiconductor base portion; and
wherein a top of the first source/drain insulation layer is disposed below a top of the first semiconductor base portion and a top of the second source/drain insulation layer is disposed above a top of the second semiconductor base portion.
